(19) United States
(12) Patent Application Publication
(10) Pub. No.: US 2004/0120191 A1
(43) Pub. Date: Jun. 24, 2004

(54) Semiconductor circuit comparing two data rows

(75) Inventor: Yasunobu Nakase, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/601,852

(22) Filed: Jun. 24, 2003

(30) Foreign Application Priority Data
Dec. 24, 2002 (JP) 2002-372198

(51) Int. Cl. G11C 5/00

(52) U.S. Cl. 365/189.07

(57) ABSTRACT

Provided is a comparator for quickly comparing a tag information stored in a cache memory with a reference tag information outputted from a CPU. A sense enable signal (SE), which controls the active state of a sense amplifier (SA) performing the output of a tag information (TM) stored in a TAG-RAM, is used to compare the tag information (TM) with a reference tag information (TC) outputted from the CPU.

### BACKGROUND OF THE INVENTION

1. Field of the Invention

The present invention relates to a semiconductor circuit having a comparator for comparing two multi-bit data.

2. Description of the Background Art

On the occasions of reading necessary data from a cache memory, a comparator is used to judge whether the read data is the necessary data or not. As a conventional comparator, for example, Japanese Patent Unexamined Publication No. 1-296338 (FIGS. 1 and 4) presents one configured by a plurality of exclusive OR circuits and an AND circuit.

With this conventional comparator, however, it is impossible to perform judgment processing of multi-bit data in a simple circuit design at an optimum timing, and therefore the judgment processing requires some time.

### SUMMARY OF THE INVENTION

It is an object of the present invention to provide a semiconductor circuit having a comparator for comparing multi-bit data rapidly.

According to the present invention, a semiconductor circuit includes a storage unit and a comparator. The storage unit stores a first multi-bit data. The comparator compares the first data with a second multi-bit data, and its active state is controlled based on a first control signal that controls the output of the first data from the storage unit.

In a simple circuit design, the active stage of the comparator can be controlled at an optimum timing in consideration of high-speed operation of the comparator. It is therefore possible to minimize the time difference between when the first data is read out and when the comparator initiates the operation. This leads to high speed of the judgment processing in the comparator as a whole.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram to explain a comparison between a tag information read from a cache memory and a reference tag information;

FIG. 2 is a diagram showing the flow of input/output signals to a TAG-RAM;

FIG. 3 is a circuit diagram showing a concrete configuration of an exclusive OR circuit according to a first preferred embodiment of the present invention;

FIG. 4 is a circuit diagram showing the flow of generating a second activation signal from a first activation signal;

FIG. 5 is a circuit diagram showing a concrete configuration of an AND circuit of the first preferred embodiment;

FIG. 6 is a circuit diagram showing a concrete configuration of a TAG-RAM of the first preferred embodiment;

FIG. 7 is a circuit diagram showing a concrete configuration of a sense amplifier;

FIG. 8 is a timing chart to explain the operation of a comparator of the first preferred embodiment;

FIG. 9 is a circuit diagram showing a concrete configuration of an exclusive OR circuit according to a second preferred embodiment of the invention;

FIG. 10 is a circuit diagram showing a concrete configuration of an AND circuit of the second preferred embodiment;

FIG. 11 is a timing chart to explain the operation of a comparator of the second preferred embodiment;

FIG. 12 is a circuit diagram showing a concrete configuration of a TAG-RAM according to a third preferred embodiment of the invention;

FIG. 13 is a diagram showing a circuit that generates a signal for controlling the operation of an AND circuit;

FIG. 14 is a circuit diagram showing a concrete configuration of an AND circuit according to a fourth preferred embodiment of the invention;

FIG. 15 is a timing chart to explain the operation of a comparator of the fourth preferred embodiment;

FIG. 16 is a circuit diagram showing a concrete configuration of an AND circuit according to a fifth preferred embodiment of the invention;

FIG. 17 is a timing chart to explain the operation of a comparator of the fifth preferred embodiment;

FIG. 18 is a circuit diagram showing a concrete configuration of a sense amplifier and exclusive OR circuit according to a sixth preferred embodiment of the invention; and

FIG. 19 is a circuit diagram showing a concrete configuration of an AND circuit of the sixth preferred embodiment.

### DESCRIPTION OF THE PREFERRED EMBODIMENTS

In general, the operation speed of memory is lowered as its storage capacity is increased. Therefore, the operation speed of a main memory having a large capacity is lower than the operation speed of a CPU (central processing unit). This causes a reduction in the instruction execution speed of the CPU.

Now limit the period of time, there is such a tendency that data necessary for the CPU are not present uniformly over the entire region of the main memory but localized to a certain region. If the data necessary for the CPU is limited to a certain region of the main memory, only data having a high frequency of access from the CPU may be stored in a memory of small storage capacity such that the CPU provides necessary data from this memory of small capacity.

To solve the above problem, between the CPU and main memory, a high speed memory having a small capacity (hereinafter referred to as a “cache memory”) is disposed so as to store data having a high frequency of access from the CPU. This enables to solve the problem that the instruction execution speed of the CPU is lowered due to a low-speed main memory.

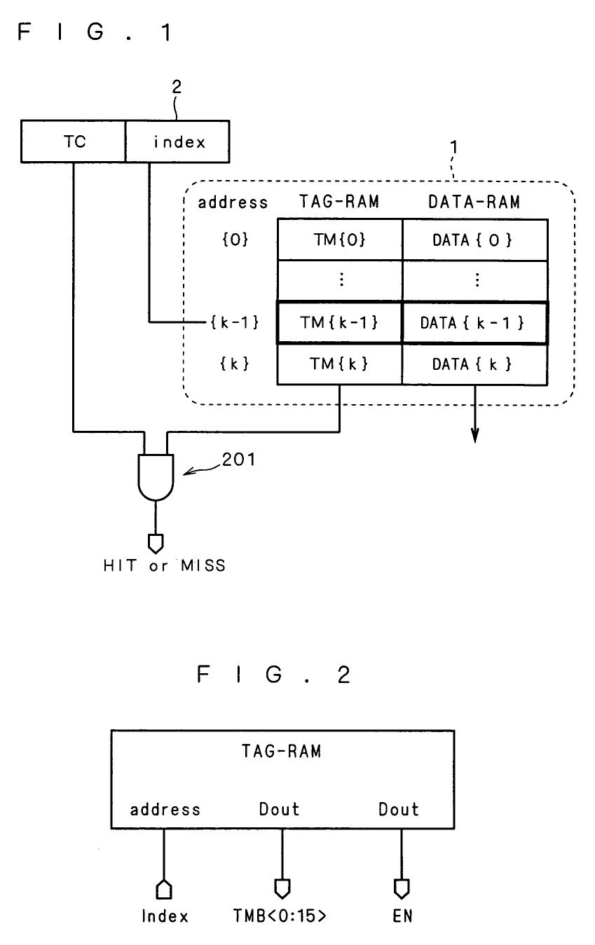

Referring now to FIG. 1, a cache memory 1 is usually configured by a portion storing data (DATA-RAM) and a portion storing tag information (TAG-RAM) for reading the data stored in the DATA-RAM.

Data is written in the cache memory 1 in the following manner.

In direct mapped, a lower bit (hereinafter referred to as an “Index”) of an address data 2 outputted from a CPU is used for designating an address of the cache memory 1. An upper bit of the address data 2 is stored as a tag information TM in the TAG-RAM corresponding to the address of the cache memory 1 designated by the Index, and data that should be written now is written in the DATA-RAM.

Data is read from the cache memory 1 in the following manner.

Firstly, the CPU outputs the address data 2 in order to read data required now.

Subsequently, the CPU accesses a predetermined address in the cache memory 1 by using the Index of the address data 2. For example, it is assumed that the predetermined address of the cache memory 1 designated by the Index is {k−1}. Then, a tag information TM {k−1} written in the TAG-RAM corresponding to the address {k−1}, and data {k−1} written in the DATA-RAM are read concurrently.

Subsequently, it is judged whether the read data is the data required by the CPU.

This judgment processing is performed by a comparator 201 which compares a reference tag information TC that is an upper bit of the address data 2 outputted from the CPU, with the tag information TM {k−1} stored in the TAG-RAM that corresponds to the address {k−1} read from the cache memory 1.

As result of the above judgment, if the two information match, the read data can be recognized as the desired data, and therefore the CPU can use the read data. This is called “cache hit” (hereinafter referred to as “HIT”). On the other hand, if a mismatch occurs, it is recognizable that the desired data is not present in the cache memory 1 (which is called “cache miss,” and hereinafter referred to as “MISS”). It is therefore necessary to read the desired data from the main memory.

In the following preferred embodiments, the circuit configuration and operation of the comparator 201 and TAG-RAM in a semiconductor circuit of the present invention will be described in detail based on the accompanying drawings.

In the present invention, it is assumed that a tag information TM and reference tag information TC are each a bit string of 16 bits. The bits configuring the tag information TM are referred to as a “tag information bit TMB <i>,” and the bits configuring the reference tag information TC are referred to as a “reference bit TCB <i>,” wherein i is 0 to 15.

First Preferred Embodiment

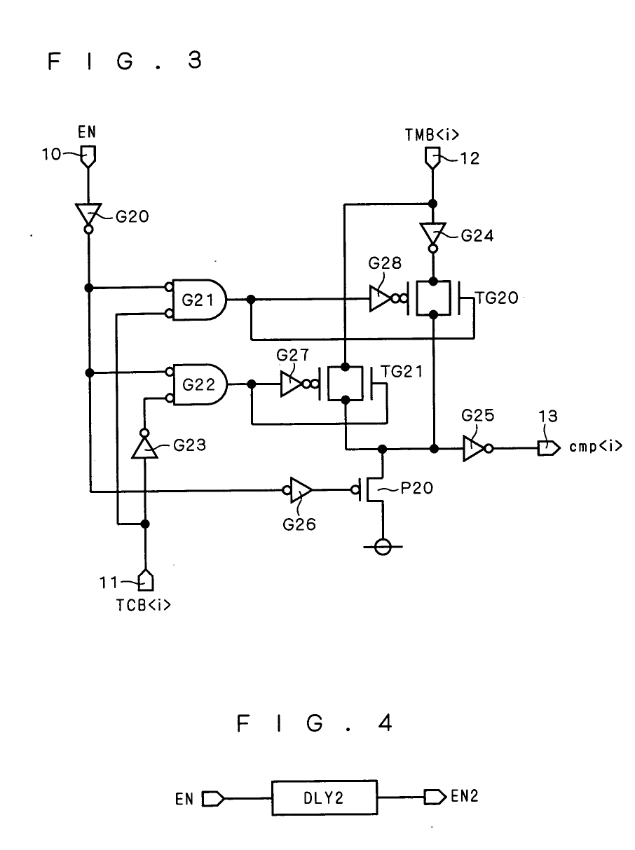

A semiconductor circuit according to a first preferred embodiment of the present invention will be described by referring to FIGS. 2 to 7.

FIG. 2 is a diagram showing the flow of input/output signals in a TAG-RAM that is part of a cache memory.

Referring to FIG. 2, an Index that is a lower bit of an address data 2 outputted from a CPU is used for address designation in the cache memory 1, and inputted as an input signal to the TAG-RAM. Then, a tag information bit TMB <i> read by the Index and an activation signal EN are outputted.

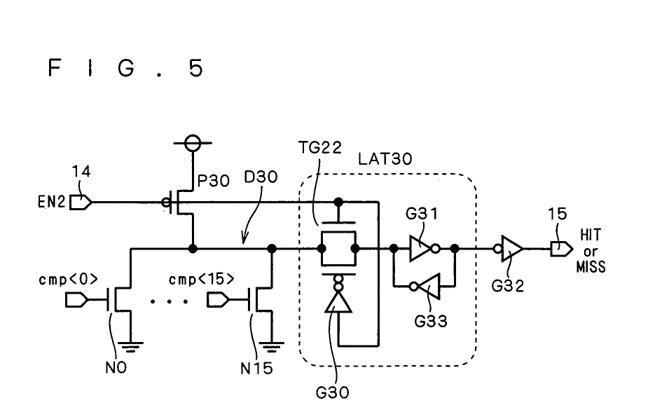

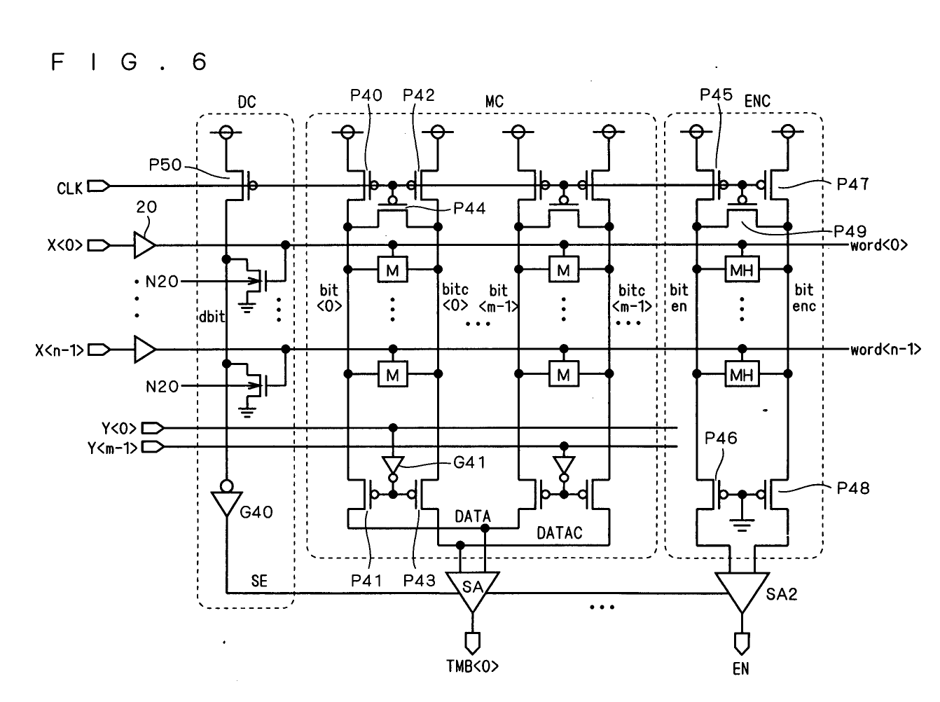

FIG. 3 is a diagram showing a concrete configuration of an exclusive OR circuit (hereinafter referred to as an “XOR circuit”) that is a front-stage circuit configuring the comparator 201 and performs an exclusive OR operation between the tag information bit TMB <i> and reference bit TCB <i>. FIG. 4 is a circuit diagram showing the flow that the activation signal EN is converted to an activation signal EN2 having a time delay by a delay circuit DLY2. FIG. 5 is a diagram showing a concrete configuration of an AND circuit that is a back-stage circuit configuring the comparator 201 and obtains an AND of output signals from a plurality of XOR circuits.

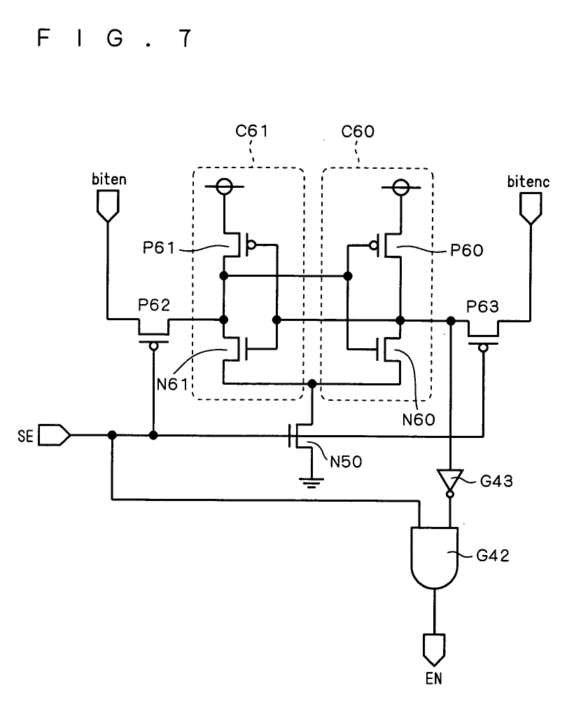

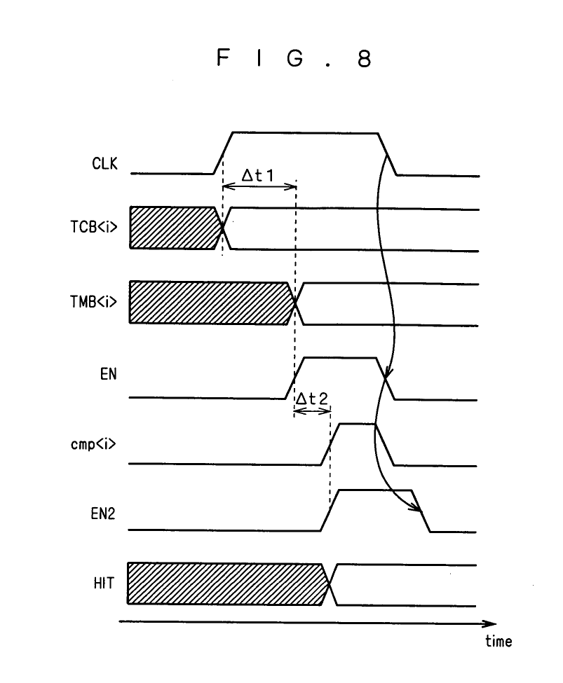

FIG. 6 is a diagram showing a memory part MC that is a major part of the TAG-RAM in FIG. 2, a column ENC for generating an activation signal, and a dummy column DC for generating a sense enable signal. FIG. 7 is a diagram showing a concrete configuration of a sense amplifier SA2 used for generating the activation signal EN in FIG. 6.

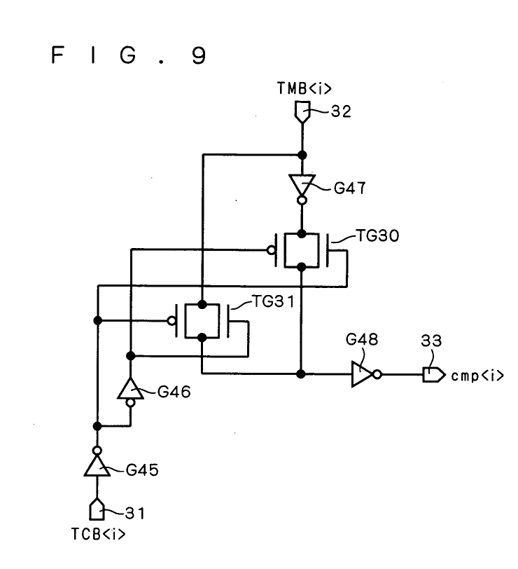

FIG. 8 is a timing chart to explain the operation of the semiconductor circuit of the first preferred embodiment.

Followings are circuit configurations in the above-mentioned drawings.

<Circuit Configuration>

Description will now be made of the XOR circuit configuration shown in FIG. 3, in which active state/inactive state are controlled by the activation signal EN. On the assumption that the tag information TM and reference tag information TC are each a bit string of 16 bits, there are disposed the XOR circuits of a number corresponding to the number of the bits (that is 16).

The XOR circuit of FIG. 3 has three input parts 10, 11, and 12, and one output part 13. Specifically, the activation signal EN is inputted to the input part 10, the reference bit TCB <i> is inputted to the input part 11, the tag information bit TMB <i> is inputted to the input part 12, and the output part 13 outputs an exclusive OR signal cmp <i> that an exclusive OR operation result obtained in the XOR circuit.

The input part 10 is connected via an inverter G20 to one input part of an NOR gate G21 and one input part of an NOR gate G22. The input part 10 is also connected via the inverter G20 and an inverter G26 to the gate of a P-type transistor P20. A fixed power source is connected to the source of the P-type transistor P20, and the drain of the P-type transistor P20 is connected via an inverter G25 to the output part 13.

The input part 11 is directly connected to the other input part of the NOR gate G21 and also connected via an inverter G23 to the other input part of the NOR gate G22.

The output part of the NOR gate G21 is connected via an inverter G28 to a P-type gate of a transmission gate TG20 and also directly connected to an N-type gate of the transmission gate TG20. The output part of the NOR gate G22 is connected via an inverter G27 to a P-type gate of a transmission gate TG21 and also directly connected to an N-type gate of the transmission gate TG21.

The input part 12 is connected via an inverter G24 to the input part of the transmission gate TG20 and also directly connected to the input part of the transmission gate TG21. Both of the output part of the transmission gate TG20 and the output part of the transmission gate TG21 are connected via the inverter G25 to the output part 13.

Following is the configuration of the AND circuit of FIG. 5, which is a circuit for obtaining an AND of exclusive OR signals cmp <i> from the output part 13 of each XOR circuit shown in FIG. 3, and which is a dynamic circuit. Hereat, the dynamic circuit is such a circuit that if once given an input signal in its active state, the corresponding output signal is determined and this output signal remains unchanged even if given other input signal, unless otherwise the AND circuit is precharged.

The AND circuit of FIG. 5 has (i) N-type transistors N0 to N15, which are 16 in number corresponding to the number of the exclusive OR signals cmp <0:15>, (ii) an input part 14 to which the activation signal EN2 is inputted which is obtained by giving a time delay to the activation signal EN by the delay circuit DLY2 of FIG. 4, (iii) a latch circuit LAT30, and (iv) an output part 15 outputting a judgment signal that is an AND operation result (HIT or MISS).

A wiring D30 is connected to the input part of the transmission gate TG22. A plurality of N-type transistors N0 to N15 (16 in number here) for AND operation are connected in parallel to each other between the wiring D30 and ground. The source and drain of each of the N-type transistors N0 to N15 are connected to the ground side and wiring D30 side, respectively. The exclusive OR signals cmp <0:15> outputted from the XOR circuit in FIG. 3 are inputted to the gates of the N-type transistors N0 to N15, respectively.

The input part 14 is connected to the gate of a P-type transistor P30. The source and drain of the P-type transistor P30 are connected to a fixed power source and the wiring D30, respectively.

Further, the input part 14 is connected to an N-type gate of the transmission gate TG22 and also connected via an inverter G30 to a P-type gate of the transmission gate TG22.

The output part of the transmission gate TG22 is connected via inverters G31 and G32 to the output part 15. A feedback inverter G33 is connected in parallel between the input part and output part of the front-stage inverter G31.

In the above-mentioned configuration, the transmission gate TG22 and inverters G30, G31, and G33 configure the latch circuit LAT30 that is controlled by the activation signal EN2.

Following is a concrete configuration of the TAG-RAM of FIG. 6, which is configured by the memory part MC that is a major part of the TAG-RAM, column ENC for generating an activation signal, and dummy column DC for generating a sense enable signal SE (regarded as a first control signal).

It is noted that the TAG-RAM usually holds the preceding tag information bit TMB <i> until a new tag information bit TMB <i> is read out, and therefore the XOR circuit of FIG. 2 has to initiate operation after a tag information bit TMB <i> desired to judge now is read out. Otherwise, an operation result based on the preceding tag information bit TMB <i> is outputted from the XOR circuit, so that an AND circuit that is a dynamic circuit located at the back-stage outputs a wrong judgment signal.

Taking the operation speed of the XOR circuit into consideration, the activation signal EN for controlling the timing of operation of the XOR circuit is preferably provided at the same time as the tag information bit TMB <i>.

Consequently, the circuit shown in FIG. 6 is configured such that a path for reading the activation signal EN is common to a path for reading the tag information bit TMB <i>, in order to generate the activation signal EN at approximately the same time as the readout of the tag information bit TMB <i> stored in the TAG-RAM.

Referring to FIG. 6, the configuration of the memory part MC will first be described.

A plurality of memory cells M are arranged in a matrix (m×n). Bit lines bit <i> and bitc <i> common in columns are connected at the opposite sides of each memory cell M. A word line word <i> common in rows is connected to each memory cell M. That is, m memory cells M are connected to each word line word <i>, and n memory cells M are connected to each bit line bit<i> and each bitc <i>.

Specifically, tag information bits TMB <0> corresponding to the addresses {0:k (=16m×n)} of the cache memory 1 are stored in the memory cells M corresponding to the initial matrix element aij (i=0, 1, . . . , m−1; and j=0, 1, . . . , n−1), respectively. Tag information bits TMB <1> corresponding to the addresses {0:k (=16m×n)} of the cache memory 1 are stored in the memory cells M corresponding to the next matrix element bik (i=m, m+1, . . . , 2m−1; and k=0, 1, . . . , n−1), respectively. Tag information bits TMB <15> corresponding to the addresses {0:k (=16m×n)} of the cache memory 1 are stored in the memory cells M corresponding to the final matrix element cil (i=15m, 15m+1, . . . , 16m−1; and l=0, 1, . . . , n−1), respectively.

In FIG. 6, only the memory cells M storing the tag information bit TMB <0> corresponding to the addresses {0:k} of the cache memory 1 are shown for simplicity. Although the configuration of a circuit part including the memory cells M storing the tag information bit TMB <0> will be described below, this is true for circuit parts including the memory cells M storing other tag information bits TMB <1:15>.

One end of each bit line bit <0:m−1> is connected via a P-type transistor P40 to a fixed power source, and the other end is connected via a P-type transistor P41 to a data line DATA. One end of each bit line bitc <0:m−1> is connected via a P-type transistor P42 to a fixed power source, and the other end is connected via a P-type transistor P43 to a data line DATAC.

A P-type transistor P44 is connected so as to bridge bit lines bit <i> and bitc <i> that are connected to a single memory cell M. A clock signal CLK is inputted in common to the respective gates of the P-type transistors P40, P42, and P44.

There are a plurality of wirings (m in number here) for sending column address signals Y<0:m−1>. With respect to the corresponding column, these wirings are connected via an inverter G41 to the gates of the P-type transistors P41 and P43, respectively.

The data line DATA is connected to one input part of the sense amplifier SA, and the data line DATAC is connected to the other input part. The output part of the sense amplifier SA is connected to the input part 12 of the XOR circuit in FIG. 3 that configures the comparator 201.

A latch circuit for holding a tag information bit TMB <i> and a driver for driving data (which are not shown in FIG. 6) are usually connected to the output side of the sense amplifier SA. Once this latch circuit reads a tag information bit TMB <i>, this tag information bit TMB <i> is continuously held and outputted until the next tag information bit TMB <i> is read out.

Following is the configuration of the column ENC for generating an activation signal.

Memory cells MH of a number (n in number here) that corresponds to the number of word lines word <0:n−1> are arranged in a column. One word line word <i> and bit lines biten and bitenc are connected to one memory cell MH.

The internal circuit of each memory cell MH is designed such that when data is read from the memory cell MH, the bit line biten is always at “H” level and the bit line bitenc is always at “L” level.

One end of the bit line biten is connected via a P-type transistor P45 to a fixed power source, and the other end is connected via a P-type transistor P46 to one input part of a sense amplifier SA2. One end of the bit line bitenc is connected via a P-type transistor P47 to a fixed power source, and the other end is connected via a P-type transistor P48 to the other end of the sense amplifier SA2. A P-type transistor P49 is connected so as to bridge the bit lines biten and bitenc.

A clock signal CLK is inputted in common to the respective gates of the P-type transistors P45, P47, and P49. The respective gates of the P-type transistors P46 and P48 are connected to ground.

The foregoing is the configuration of the column ENC. The output part of the sense amplifier SA2 is connected to the input part 10 of the XOR circuit in FIG. 3 that configures the comparator 201.

Following is the configuration of the dummy column DC generating a sense enable signal SE for activating the sense amplifiers SA and SA2 shown in FIG. 6.

N-type transistors N20 of a number corresponding to the number of word lines word <0:n−1> are arranged in a column. The gate of each N-type transistor N20 is connected one word line <i>, and its drain and source are connected to a dummy bit line dbit and ground, respectively.

One end of the dummy bit line dbit is connected via a P-type transistor P50 to fixed power source, and the other end is connected to the input part of an inverter G40. The output part of the inverter G40 is connected to the sense amplifiers SA and SA2 for controlling their respective active states.

A clock signal CLK is inputted to the gate of the P-type transistor P50.

The foregoing is the configuration of the dummy column DC.

As described above, the memory part MC, column ENC, and dummy column DC configure the TAG-RAM.

Following is the circuit configuration of FIG. 7 showing a concrete configuration of the sense amplifier SA2 used in the column ENC for generating an activation signal EN. As previously described, as a signal for controlling the active state/inactive state of the sense amplifier SA2, the sense enable signal SE common to another sense amplifier SA is used.

A P-type transistor P60 and an N-type transistor N60 are connected in series to configure a CMOS inverter C60. A P-type transistor P61 and an N-type transistor N61 are connected in series to configure a CMOS inverter C61. The respective input/output parts of the CMOS inverters C60 and C61 are mutually connected to obtain mutually connected CMOS inverters.

The respective sources of the P-type transistors P60 and P61 are connected to a fixed power source. The respective sources of the N-type transistors N60 and N61 are connected via an N-type transistor N50 to ground.

The output part of the CMOS inverter C61 is connected via a P-type transistor P62 to the bit line biten. The output part of the CMOS inverter C60 is connected via a P-type transistor P63 to the bit line bitenc.

The inverter G40 shown in FIG. 6 is connected in common to the respective gates of the P-type transistors P62 and P63, and the gate of the N-type transistor N50, and also connected to one input part of an AND gate G42. The other input part of the AND gate G42 is connected via an inverter G43 to the CMOS inverter C60, and the output part of the AND gate G42 is connected to the input part 10 of the XOR circuit shown in FIG. 3 that configures the comparator 201.

The foregoing is the configuration of the comparator 201 and TAG-RAM that configure the semiconductor circuit of the first preferred embodiment.

A description will next be made of the operation of the above-mentioned configurations, based on a timing chart shown in FIG. 8. The following description is directed to a reference bit TCB <i> that is a predetermined i-th bit configuring the reference tag information TC, and a tag information bit TMB <i> that is a predetermined i-th bit configuring the tag information TM. This is true for other reference bits TCB <0, . . . , i−1, i+1, . . . , 15> and other tag information bits TMB <0, . . . , i−1, i+1, . . . , 15>.

<Circuit Operation>

A description will first be made of the operation of the XOR circuit shown in FIG. 3, which is located at the front-stage configuring the comparator 201.

First, in synchronization with a leading edge of a clock signal CLK, an address data 2 is outputted from the CPU, and a reference bit TCB <i> configuring a reference tag information TC that is an upper bit of the address data 2 is inputted to each XOR circuit. At the same time, an Index that are lower bits of the address data 2 is inputted to the TAG-RAM shown in FIG. 2, thereby initiating readout of a tag information bit TMB <i>.

Until the tag information bit TMB <i> is read out, it is necessary to hold a signal of “L” level as an exclusive OR signal cmp <i> outputted from the output part 13 of each XOR circuit.

This is because the AND circuit of FIG. 5 connected to the back-stage of each XOR circuit is a dynamic circuit which is required to be ready for the subsequent judgment processing by precharging the wiring D30 by the P-type transistor P30 until the operation is started.

That is, once inputted “H” level as an exclusive OR signal cmp <i> that is an intermediate result, the precharging by the P-type transistor P30 is not effective, and therefore the wiring D30 is set to “L” level.

Consequently, even if thereafter the AND circuit enters the active state and the exclusive OR signal cmp <i> that is a real operation result becomes “L” or “H” level, the output part 15 always outputs “L” level as a judgment signal, failing to perform a proper AND operation based on the individual exclusive OR signal cmp <i>.

Therefore, as shown in FIG. 8, an activation signal EN is fixed at “L” level until the tag information bit TMB <i> is read out.

By doing so, the P-type transistor P20 shown in FIG. 3 enters the on state, so that “L” level is held as the exclusive OR signal cmp <i> (i.e., the inactive state of the XOR circuit). As the result, the precharging to the wiring D30 with the use of the P-type transistor of an AND circuit is made effective until the tag information bit TMB <i> is read out. Thereafter, when the AND circuit enters the active state, it is possible to perform a proper AND operation according to the exclusive OR signal cmp <i> that is a real operation result.

When time Δt1 is elapsed since the Index was inputted to the TAG-RAM of FIG. 2, a tag information bit TMB <i> is outputted from the TAG-RAM. At approximately the same time, an activation signal EN of “H” level is outputted.

Then, a signal of “H” level is inputted to the gate of the P-type transistor P20 in FIG. 3, and the transistor P20 enters the off state, so that an exclusive OR operation between the tag information bit TMB <i> and reference bit TCB <i> is started (i.e., the active state of the XOR circuit).

In this state, for example, in a first case that both of the tag information bit TMB <i> and reference bit TCB <i> are at “H” level, a signal of “L” level is inputted to one input part of the NOR gate G21, and a signal of “H” level is inputted to the other input part, so that a signal of “L” level is outputted from the output part of the NOR gate G21. As the result, the transmission gate TG20 enters the off state.

On the other hand, a signal of ‘L” level is inputted to one input part of the NOR gate G22, and a signal of L” level is inputted to the other input part, so that a signal of “H” level is outputted from the output part of the NOR gate G22. As the result, the transmission gate TG21 enters the on state. Then, the tag information bit TMB <i> is inverted by the inverter G25, and therefore an exclusive OR signal cmp <i> of “L” level is outputted from the output part 13.

In a second case that the activation signal EN is at “H” level and both of the tag information bit TMB <i> and reference bit TCB <i> are at “L” level, a signal of “L” level is inputted to one input part of the NOR gate G22, and a signal of “H” level is inputted to the other input part, so that a signal of “L” level is outputted from the output part of the NOR gate G22. As the result, the transmission gate TG21 enters the off state.

On the other hand, a signal of ‘L” level is inputted to one input part of the NOR gate G21, and a signal of L” level is inputted to the other input part, so that a signal of “H” level is outputted from the output part of the NOR gate G21. As the result, the transmission gate TG20 enters the on state. Then, the tag information bit TMB <i> is inverted twice by the inverters G24 and G25, and therefore an exclusive OR signal cmp <i> of “L” level is outputted from the output part 13.

In a third case that the activation signal EN is at ‘H” level, the tag information bit TMB <i> is at “H” level, and the reference bit TCB <i> is at “L” level, a signal of “L” level is inputted to one input part of the NOR gate G22, and a signal of “H” level is inputted to the other input part, so that a signal of “L” level is outputted from the output part of the NOR gate G22. As the result, the transmission gate TG21 enters the off state.

On the other hand, a signal of ‘L” level is inputted to one input part of the NOR gate G21, and a signal of L” level is inputted to the other input part, so that a signal of “H” level is outputted from the output part of the NOR gate G21. As the result, the transmission gate TG20 enters the on state. Then, the tag information bit TMB <i> is inverted twice by the inverters G24 and G25, and therefore an exclusive OR signal cmp <i> of “H” level is outputted from the output part 13.

In a fourth case that the activation signal EN is at “H” level, the tag information bit TMB <i> is at “L” level, and the reference bit TCB <i> is at “H” level, a signal of “L” level is inputted to one input part of the NOR gate G21, and a signal of “H” level is inputted to the other input part, so that a signal of “L” level is outputted from the output part of the NOR gate G21. As the result, the transmission gate TG20 enters the off state.

On the other hand, a signal of “L” level is inputted to one input part of the NOR gate G22, and a signal of “L” level is inputted to the other input part, so that a signal of “H” level is outputted from the output part of the NOR gate G22. As the result, the transmission gate TG21 enters the on state. Then, the tag information bit TMB <i> is inverted by the inverter G25, and therefore an exclusive OR signal cmp <i> of “H” level is outputted from the output part 13.

As can be seen from the above, when the level of the tag information bit TMB <i> matches that of the reference bit TCB <i>, the exclusive OR signal cmp <i> of “L” level is outputted. On the other hand, when they do not match, the exclusive OR signal cmp <i> of “H” level is outputted.

Following is the operation of the AND circuit of FIG. 5 that is located at the back-stage configuring the comparator 201.

Assuming that on the XOR circuit of FIG. 3, it takes time Δt2 from the input of the tag information bit TMB <i> to the establishment of the exclusive OR signal cmp <i>, the delay circuit DLY2 having a time delay value of Δt2 is disposed in FIG. 4. By doing so, the activation signal EN2 has a time delay of Δt2 with respect to the activation signal EN.

Accordingly, the activation signal EN2 is at “L” level until the activation signal EN2 rises (during the period of time that the exclusive OR signal cmp <i> is established in the XOR circuit of FIG. 3). Therefore, the P-type transistor P30 of the AND circuit is in the on state and performs precharging to the wiring D30 (i.e., the inactive state of the AND circuit).

During the period of time that the activation signal EN2 is at “L” level, the transmission gate TG22 of the latch circuit LAT30 is in the off state, and therefore the judgment signal holds the preceding value.

Then, when time Δt2 is elapsed since the tag information bit TMB <i> was read out, the activation signal EN2 rises and is set to “H” level, the P-type transistor P30 enters the off state and the transmission gate TG22 enters the on state.

In this state, when all the exclusive OR signals cmp <0:15> established at the front-stage are at “L” level (i.e., when the tag information TM matches the reference tag information TC), all the N-type transistors N0 to N15 configuring the AND circuit of FIG. 5 enter the off state, and therefore the potential of the wiring D30 remains at “H” level.

Since the transmission gate TG22 is now in the on state, the above “H” level is taken by the latch circuit LAT30, and a judgment signal of “H” level is outputted from the output part 15 via the inverters G31 and G32. That is, when the tag information TM completely matches the reference tag information TC (i.e., in the case of HIT), a signal of “H” level is outputted as a judgment signal.

On the other hand, when at least one of the exclusive OR signals cmp <0:15> established at the front-stage is at “H” level (i.e., when the tag information TM does not match the reference tag information TC), an N-type transistor to which this signal of “H” level is inputted enters the on state, and therefore the potential of the wiring D30 is changed to a ground potential, namely “L” level.

Since the transmission gate TG22 is now in the on state, the above “L” level is taken by the latch circuit LAT30, and a judgment signal of “L” level is outputted from the output part 15 via the inverters G31 and G32. That is, when the tag information TM does not match the reference tag information TC (i.e., in the case of MISS), a signal of “L” level is outputted as a judgment signal.

In the foregoing manner, with the comparator 201 configured by the XOR circuit, AND circuit etc. shown in FIGS. 3, 4, or 5, a comparison between the tag information TM and reference tag information TC is performed properly. In order to change the AND circuit into its active state at an optimum timing, one capable of generating a time delay of time Δt2 is employed as the delay circuit DLY2 in FIG. 4. Of course, a delay circuit DLY2 having more delay time may be employed to ensure a reliable operation on the AND circuit.

Since the dynamic circuit is used as the AND circuit of FIG. 5, as previously described, the XOR circuit of FIG. 2 is required to change to its active state after the tag information bit TMB <i> is read out. Further, in consideration of operation speed, it is desirable that the activation signal EN is provided at the same time as the tag information bit TMB <i>. Accordingly, the TAG-RAM circuit of FIG. 6 is configured to enable this operation.

Following is the operation of the TAG-RAM circuit in FIG. 6. Reference characters X <0> to X <n−1> indicate a row address signal, and Y <0> to Y <m−1> indicate a column address signal. By the row address signal and column address signal, a predetermined memory cell M is selected and a tag information bit TMB <i> is read out. Although the operation of the memory part MC will be described by taking as example a block storing a tag information bit TMB <0>, this is true for other blocks storing other tag information bits TMB <1:15>.

Referring now to FIG. 8, when a clock signal CLK is at “L” level, in the memory part MC, P-type transistors P40, P42, and P44 enter the on state, so that all bit lines bit <0:m−1> and bitcs <0:m−1> are precharged to “H” level by a fixed power source.

Also in the dummy column DC, when a clock signal CLK is at “L” level, the P-type transistor P50 enters the on state, so that a dummy bit line dbit is precharged to “H” level by a fixed power source. Then, a sense enable signal SE is set to “L” level, and the sense amplifiers SA and SA2 are changed to their inactive states.

Following is the operation of the column ENC.

When the clock signal CLK is at “L” level, in FIG. 6, the P-type transistors P45, P47, and P49 enter the on state, so that a bit line biten and bitenc are precharged to “H” potential. Since the gates of the P-type transistors P46 and P48 are connected to ground, they are always in the on state.

Further, when the clock signal CLK is at “L” level, the sense enable signal SE becomes “L” level. Therefore, in FIG. 7, the P-type transistors P62 and P63 enter the on state and the N-type transistor N50 enters the off state, so that a signal of L” level is inputted to the both input parts of the AND gate G42.

Consequently, when the clock signal CLK is at “L” level, the activation signal EN of “L” level is outputted from the output part of the AND gate G42. Even if the clock signal CLK rises, during the period of time that the sense enable signal SE is at “L” level, an activation signal EN of “L” level is outputted from the AND gate G42.

Thereby, as described above, the P-type transistor P20 of FIG. 3 enters the on state, and “L” level is held as an exclusive OR signal cmp <i> (i.e., the XOR circuit is controlled in its inactive state). As the result, the precharging to the wiring D30 with the use of the P-type transistor P30 of the AND circuit is made effective until the tag information bit TMB <i> is read out. Thereafter, when the AND circuit enters the active state, it is possible to perform a proper AND operation based on the exclusive OR signal cmp <i> that is a real operation result.

Subsequently, when the clock signals CLK rises to “H” level, all the P-type transistors P40, P42, P44, P45, P47, P49, and P50 enter the off state, and the precharging of all the bit lines is interrupted, thereby initiating the readout of the tag information bit TMB <0>.

A description will first be made of the operation of the memory part MC.

During the period of time that the clock signal CLK is at “H” level, for example, if a row address signal X<0> of “H” level is set, the potential of a word line word <0> becomes “H” level via a buffer 20. Then, the data stored in all the memory cells M connected to the word line word <0> are read out to their respective bit lines bit <0:m−1> and bitc <0:m−1>.

Subsequently, for example, if a column address signal Y <0> of “H” level is set, the P-type transistor P41 connected to the bit line bit <0> and the P-type transistor P43 connected to the bit lines bitc <0> enter the on state, so that the signal of the bit line bit <0> is transmitted to the data line DATA and the signal of the bit line bitc <0> is transmitted to the data line DATAC.

Thereafter, when the sense enable signal SE of “H” level is inputted, the sense amplifier SA enters the active state, thereby outputting a tag information bit TMB <0>.

Following is the operation of the dummy column DC.

When the word line word <0> has a potential of “H” level, the N-type transistor N20 connected to the word line word <0> enters the on state. Therefore, when time Δt1 is elapsed since discharging to a ground potential via the N-type transistor N20 was started, the potential of the dummy bit line dbit is changed from “H” level to “L” level. Therefore, when time Δt1 is elapsed since the clock signal CLK rose, the sense enable signal SE is changed to “H” level via the inverter G40, thereby changing the sense amplifiers SA and SA2 into their active states.

It is preferable to determine the size of the N-type transistor N20 such that the sense enable signal SE is of “H” level when the potential difference between the data lines DATA and DATAC connected to each sense amplifier SA is increased sufficiently by the data read from the memory cell M.

Following is the operation of the column ENC.

When the clock signal CLK rises and a row address signal X<0> of “H” level is set, the potential of the word line word <0> is changed to “H” level via the buffer 20, and a memory cell MH connected to the word line word <0> is selected. Upon this, the bit line biten is changed to “H” and the bit line bitenc is changed to “L” level by the internal circuit of the memory cell MH.

Subsequently, in this state, when time Δt1 is elapsed since the clock signal CLK rose, the sense enable signal SE rises and becomes “H” level. Then, in FIG. 7, the P-type transistors P62 and P63 enter the off state and the N-type transistor N50 enters the on state. Therefore, the sense enable signal SE of “H” level is inputted to one input part of the AND gate G42, and an amplified “H” level signal is inputted to the other input part.

As the result, the activation signal EN of “H” level is outputted from the output part of the AND gate G42.

Thus, when the sense enable signal SE is changed to “H” level, the sense amplifiers SA and SA2 enter their active states at the same time. Then, a tag information bit TMB <0> read freshly and the activation signal EN of “H” level are concurrently outputted from the sense amplifiers SA and SA2, respectively.

Thereafter, when the clock signal CLK is changed to “L” level, the dummy bit line dbit is precharged again and changed to “H” level. In accordance with this, the sense enable signal SE is changed to “L” level and the sense amplifiers SA and SA2 enter their inactive states.

Likewise, in the column ENC, when the clock signal CLK is changed to “L” level, the bit lines biten and bitenc are precharged to “H” level, and therefore the activation signal EN is again set to “L” level. At this time, the activation signal EN2 is also changed to “L” level. Thereby, the AND circuit of FIG. 5 enters the inactive state (i.e., precharged state) and, at the same time, an input transmission gate TG22 of a latch circuit LAT30 enters the off state, so that the latch circuit LAT30 holds a judgment signal.

The foregoing description is a sequence of operation in the comparator 201, TAG-RAM, etc. configuring the semiconductor circuit of the first preferred embodiment.

Firstly, according to the semiconductor circuit of the first preferred embodiment, the respective active states of the sense amplifiers SA and SA2 are controlled concurrently by using a sense enable signal SE. Thus, in this simple circuit design, the activation signal EN of “H” level can also be provided to the comparator 201 at the same time as a tag information bit TMB <i>.

That is, at the same time that a tag information bit TMB <i> is inputted to the XOR circuit, the operation based on the tag information bit TMB <i> is executable on the XOR circuit. This prevents any malfunction of the AND circuit that is a dynamic circuit. This also minimizes the time margin between when the tag information bit TMB <i> is inputted to the XOR circuit and when the operation on the XOR circuit is started.

Secondly, the active state/inactive state of the AND circuit are controlled by an activation signal EN2 generated based on an activation signal EN. Therefore, when generating the activation signal EN2, it is only required to consider the time necessary for the operation on the XOR circuit. Thus, in a simple circuit design, the activation signal EN2 for activating the AND circuit can be generated at an optimum timing.

Thirdly, a delay time of the activation signal EN2 to the activation signal EN is set to the same as the time necessary for the operation on the XOR circuit, by the delay circuit DLY2. This minimizes the time margin between when the operation on the XOR circuit is started and when the operation on the AND circuit is started, thereby reducing the time required for obtaining a judgment result in the AND circuit.

Fourthly, the use of the dynamic circuit as an AND circuit can reduce the number of circuit elements configuring the AND circuit. It is unnecessary to use a large number of multi-input logic gates as in the case of a static circuit. Therefore, a high-speed judgment processing is performable in the comparator 201 of the first preferred embodiment.

Second Preferred Embodiment

In the first preferred embodiment, the XOR circuit operation is controlled by the activation signal EN such that the AND circuit as the back-stage dynamic circuit will not cause any malfunction depending on the intermediate result of the XOR circuit output. It is unavoidable that the XOR circuit has a complicated configuration.

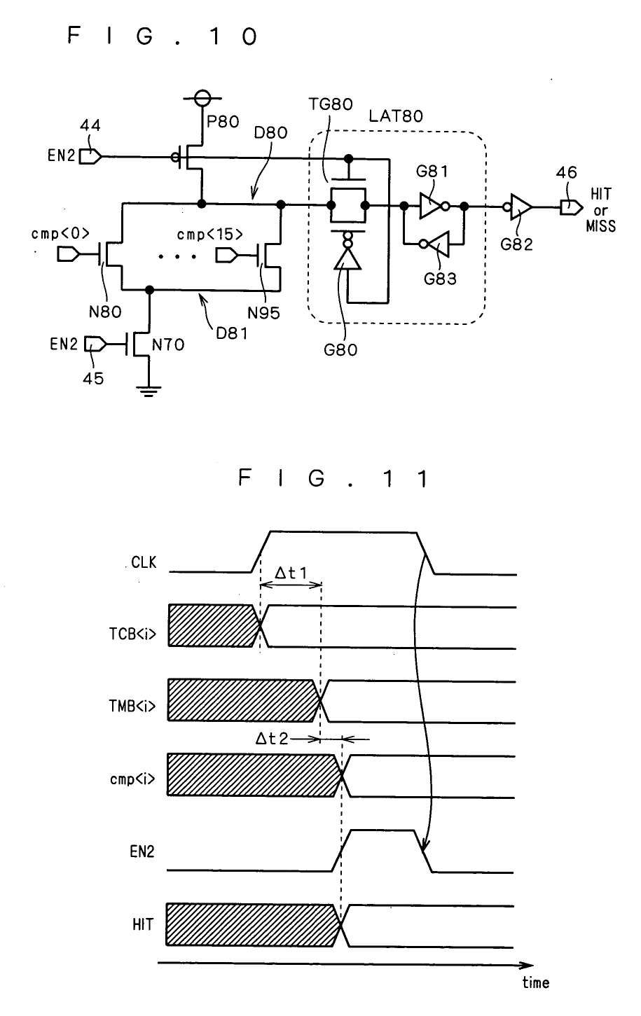

Accordingly, a second preferred embodiment of the present invention aims at simplifying the XOR circuit by eliminating the control with the activation signal EN. FIGS. 9 and 10 plot the configuration of a comparator 201 of the second preferred embodiment. As a TAG-RAM, one that has the configuration shown in FIGS. 6 and 7 is employed here.

FIG. 9 shows an XOR circuit located at the front-stage, configuring the comparator 201 of the second preferred embodiment. FIG. 10 shows an AND circuit that is a dynamic circuit located at the back-stage, configuring this comparator 201.

The circuit configuration in FIGS. 9 and 10 will be described in detail below.

<Circuit Configuration>

Following is the configuration of the XOR circuit of FIG. 9, which performs an exclusive OR operation between a tag information bit TMB <i> and reference bit TCB <i>. Since it is assumed that the tag information TM and reference tag information TC are of a bit string of 16 bits, there are disposed 16 XOR circuits corresponding to these bits.

The XOR circuit of FIG. 9 has two input parts 31 and 32, and one output part 33. A reference bit TCB <i> is inputted to the input part 31, and a tag information bit TMB <i> is inputted to the input part 32. An exclusive OR signal cmp <i> is outputted from the output part 33.

The input part 31 is connected via an inverter G45 to a P-type gate of a transmission gate TG31, and also connected via the inverter G45 to an N-type gate of a transmission gate TG30.

Further the input part 31 is connected via the inverter G45 and an inverter G46 to an N-type gate of the transmission gate TG31 and also connected via the inverters G45 and G46 to a P-type gate of the transmission gate TG30.

The input part 32 is directly connected to the input part of the transmission gate TG31 and also connected via an inverter G47 to the input part of the transmission gate TG30.

Both of the output part of the transmission gate TG30 and the output part of the transmission gate TG31 are connected via an inverter G48 to the output part 33.

Following is the configuration of the AND circuit of FIG. 10 that is a dynamic circuit and also a circuit for obtaining an AND of the exclusive OR signal cmp <i> outputted from the individual XOR circuit shown in FIG. 9. Through the delay circuit DLY2 shown in FIG. 4, an activation signal EN is converted to an activation signal EN2 having a time delay, and then inputted to the AND circuit.

Referring now to FIG. 10, an input part 44 is connected to the gate of a P-type transistor P80, and an input part 45 is connected to the gate of an N-type transistor N70. The source and drain of the P-type transistor P80 are connected to a fixed power source and a wiring D80, respectively. The source and drain of the N-type transistor N70 are connected to ground and a wiring D81, respectively.

The wiring D80 is connected to the input part of the transmission gate TG80. A plurality of N-type transistors N80 to N95 (16 in number here) are connected in parallel to each other so as to connect the wirings D80 and D81. The source and drain of each of the N-type transistors N80 to N95 are connected to the wiring D81 side and the wiring D80 side, respectively. Exclusive OR signals cmp <0:15> outputted from the XOR circuit of FIG. 9 are inputted to the gates of the N-type transistors N80 to N95, respectively.

Further the input part 44 is connected to an N-type gate of the transmission gate TG80 and also connected via the inverter G80 to a P-type gate of the transmission gate TG80.

The output part of the transmission gate TG80 is connected via inverters G81 and G82 to an output part 46 for outputting a judge signal (HIT or MISS) that is an AND operation result. A feedback inverter G83 is connected in parallel between the input and output parts of the front-stage inverter G81.

In the above configuration, the transmission gate TG80 and inverters G80, G81, G83 configure a latch circuit LAT80.

In the above-mentioned comparator 201 of the second preferred embodiment, the N-type transistor N70 is added to obtain the AND circuit of FIG. 10 because the XOR circuit is not controlled by the activation signal EN, unlike the first preferred embodiment.

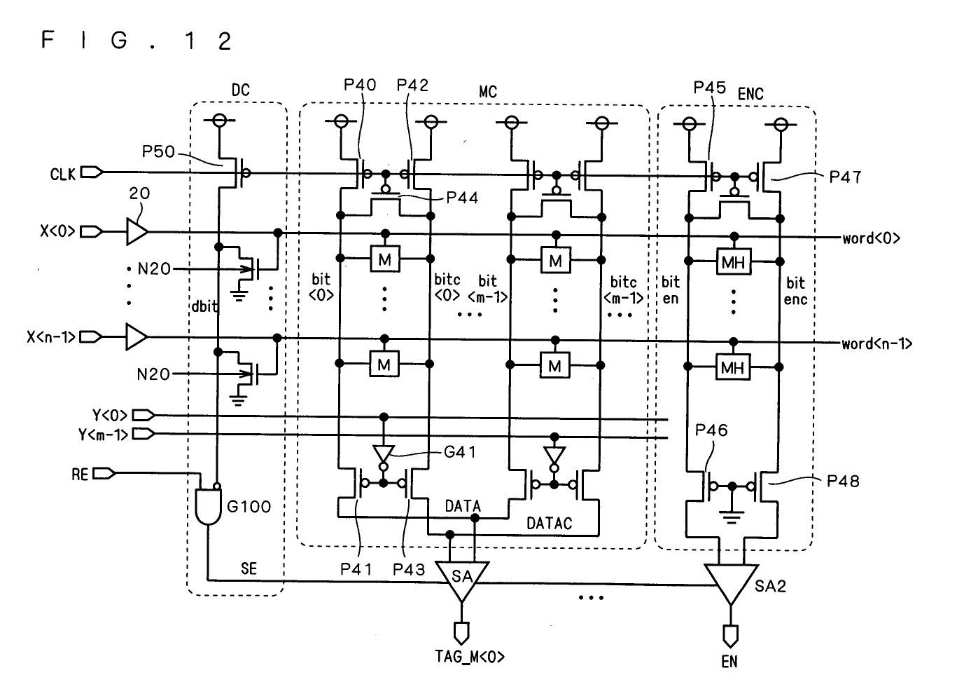

A description will next be made of the operation of the above-mentioned circuits based on a timing chart shown in FIG. 11. The following description relates to a reference bit TCB <i> that is a predetermined i-th bit configuring a reference tag information TC, and a tag information bit TMB <i> that is a predetermined i-th bit configuring a tag information TM. This is true for other reference bits TCB <0, . . . , i−1, i+1, . . . , 15> and other tag information bits TMB <0, . . . , i−1, i+1, . . . , 15>.

<Circuit Operation>

A description will now be made of the operation of the XOR circuit of FIG. 9.

First, in synchronization with a leading edge of a clock signal CLK, an address data 2 is outputted from a CPU, and a reference bit TCB <i> configuring a reference tag information TC that are upper bits of the address data 2 is inputted to each XOR circuit in FIG. 9. At the same time, an Index that are lower bits of the address data 2 is inputted to the TAG-RAM shown in FIG. 2, thereby initiating readout of a tag information bit TMB <i>.

When time Δt1 is elapsed since the Index was inputted to the TAG-RAM of FIG. 2, the tag information bit TMB <i> is outputted from the TAG-RAM. At approximately the same time, an activation signal EN of “H” level is outputted.

A latch circuit and driver (not shown) are usually disposed at the back-stage of the sense amplifier SA shown in FIG. 6. Therefore, the preceding cycle's data is held and outputted as a tag information bit TMB <i> during the period of time between the rise of the clock signal CLK and time Δt1.

Consequently, as an exclusive OR signal cmp <i>, an operation result based on the preceding tag information bit TMB <i> is outputted. However, after time Δt1, the present tag information bit TMB <i> that is desired to compare now is inputted through the input part 32. Therefore, after time Δt1, an operation result based on the present tag information bit TMB <i> is outputted as an exclusive OR signal cmp <i>.

For example, in a first case that both of the present tag information bit TMB <i> and a reference bit TCB <i> are of “H” level, the transmission gate TG30 enters the off state and the transmission gate TG31 enters the on state by a signal of “H” level inputted through the input part 31.

As the result, the present tag information bit TMB <i> of “H” level passes through the transmission gate TG31 and inverter G48, so that an exclusive OR signal cmp <i> of “L” level is outputted from the output part 33.

In a second case that both of the present tag information bit TMB <i> and reference bit TCB <i> are of “L” level, the transmission gate TG31 enters the off state and the transmission gate TG30 enters the on state by a signal of “L” level inputted through the input part 31.

As the result, the present tag information bit TMB <i> of “L” level passes through the inverter G47, transmission gate TG30, and inverter G48, so that an exclusive OR signal cmp <i> of “L” level is outputted from the output part 33.

In a third case that the present tag information bit TMB <i> is of “H” level and the reference bit TCB <i> is of “L” level, the transmission gate TG31 enters the off state and the transmission gate TG30 enters the on state by a signal of “L” level inputted through the input part 31.

As the result, the present tag information bit TMB <i> of “H” level passes through the inverter G47, transmission gate TG30, and inverter G48, so that an exclusive OR signal cmp <i> of “H” level is outputted from the output part 33.

In a fourth case that the present tag information bit TMB <i> is of “L” level and the reference bit TCB <i> is of “H” level, the transmission gate TG30 enters the off state and the transmission gate TG31 enters the on state by a signal of “H” level inputted through the input part 31.

As the result, the present tag information bit TMB <i> of “L” level passes through the transmission gate TG31 and inverter G48, so that an exclusive OR signal cmp <i> of “H” level is outputted from the output part 33.

As can be seen from the above, the exclusive OR signal cmp <i> of “L” level is outputted when the level of the tag information bit TMB <i> matches that of the reference bit TCB <i>, whereas the exclusive OR signal cmp <i> of “H” level is outputted when they do not match, as in the foregoing first preferred embodiment.

Following is the operation of the AND circuit of FIG. 10.

Assuming that on the XOR circuit of FIG. 9, time Δt2 is required between when the tag information bit TMB <i> is read out and when the exclusive OR signal cmp <i> is established, the delay circuit DLY2 having a time delay value of time Δt2 is disposed in FIG. 4. This enables to generate an activation signal EN2 having a time delay of Δt2 with respect to the activation signal EN.

Accordingly, the activation signal EN2 is at “L” level until the activation signal EN2 rises, namely until the exclusive OR signal cmp <i> is established on the XOR circuit of FIG. 9. Therefore, the P-type transistor P80 is in the on state, and performs precharging to the wiring D80. At this time, the N-type transistor N70 is in the off state (i.e., the inactive state).

During the period of time that the activation signal EN2 is at “L” level, the transmission gate TG80 of the latch circuit LAT80 enters the off state, thereby holding the preceding value as a judgment signal.

Then, when time Δt2 is elapsed since the tag information bit TMB <i> was read out, the activation signal EN2 rises and is set to “H” level, so that the P-type transistor P80 enters the off state and the transmission gate TG80 enters the on state. At this time, the N-type transistor N70 enters the on state and the wiring D81 is of a ground potential (i.e., the active state).

In this state, when all the exclusive OR signals cmp <0:15> established at the front-stage are at “L” level (i.e., when the tag information TM matches the reference tag information TC), all the N-type transistors N80 to N95 configuring the AND circuit of FIG. 10 enter the off state, and therefore the potential of the wiring D80 remains at “H” level.

Since the transmission gate TG80 is now in the on state, the above “H” level is taken by the latch circuit LAT80, and a judgment signal of “H” level is outputted from the output part 46 via the inverters G81 and G82. That is, when the tag information TM completely matches the reference tag information TC (i.e., in the case of HIT), a signal of “H” level is outputted as a judgment signal.

On the other hand, when at least one of the exclusive OR signals cmp <0:15> established at the front-stage is at “H” level (i.e., when the tag information TM does not match the reference tag information TC), the N-type transistors N80 to N95, to which this signal of “H” level is inputted, enter the on state, so that the potential of the wiring D80 is changed to a ground potential, namely “L” level.

Since the transmission gate TG80 is now in the on state, the above “L” level is taken by the latch circuit LAT80, and a judgment signal of “L” level is outputted from the output part 46 via the inverters G81 and G82. That is, when the tag information TM does not match the reference tag information TC (i.e., in the case of MISS), a signal of “L” level is outputted as a judgment signal.

In the foregoing manner, a proper judgment processing is also executable by the comparator 201 of the second preferred embodiment.

In the AND circuit of the second preferred embodiment, the active state/inactive state of the AND circuit are controlled by the two transistors P80 and N70 that have different conductivity types and are controlled by the activation signal EN2, thereby eliminating the necessity for controlling the activation on the XOR circuit.

Thus, with the XOR circuit of the second preferred embodiment, it is possible to reduce two NOR gates, one inverter, and one P-type transistor than the XOR circuit of the first preferred embodiment. In the above case, the comparison between the tag information TM of 16 bits and the reference tag information TC of 16 bits is performed by using 16 XOR circuits, and therefore, 4×16 circuit elements can be reduced in this case.

This permits a reduction in the area of the entire circuit and also a reduction in power consumption.

As previously described in the first preferred embodiment, to obtain the highest operation speed of the XOR circuit, it is necessary to concurrently provide the tag information TM and activation signal EN. In order to more reliably prevent the output of an exclusive OR signal cmp based on the preceding tag information TM, it is necessary to provide the activation signal EN slightly later than the time that the tag information TM is read out. That is, in some cases the first preferred embodiment requires a slight time margin for this reason.

Whereas in the XOR circuit of the second preferred embodiment, any control with the activation signal EN is unnecessary because the above-mentioned time margin is unnecessary. This permits a reduction in the operation time of the XOR circuit as a whole.

Third Preferred Embodiment

In the first preferred embodiment, an HIT/MISS judgment in the comparator 201 is required only when a tag information TM is read from the TAG-RAM. It is possible to reduce power consumption by configuring such that the comparator 201 is not activated when a tag information TM is written in the TAG-RAM.

Accordingly, a third preferred embodiment of the present invention aims at providing a semiconductor circuit capable of activating the comparator 201 only when a tag information TM is read from a TAG-RAM.

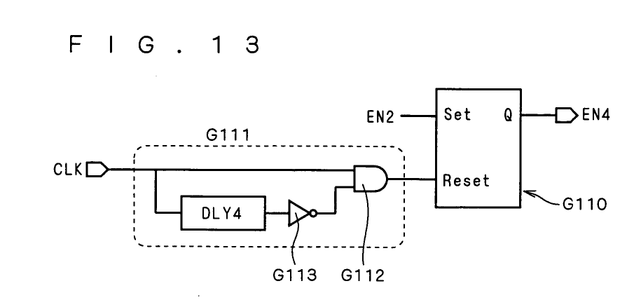

FIG. 12 is a circuit diagram of a TAG-RAM capable of activating the comparator 201 only when a tag information TM is read from the TAG-RAM. The TAG-RAM of FIG. 12 is approximately the same as that of FIG. 6, except for the following point. As a concrete configuration of a sense amplifier SA2, the configuration shown in FIG. 7 is also employed in the third preferred embodiment.

The different point is that instead of the inverter G40 (FIG. 6), an AND gate G100 is connected to the other terminal of a dummy bit line dbit in a dummy column DC (FIG. 12).

The dummy bit line dbit is connected to one input part of the AND gate G100 in such a structure that a signal is inverted before this input part. A wiring that transmits a control signal RE in accordance with the time of read/write of a tag information TM from the TAG-RAM is connected to the other input part. Like the output part of the inverter G40 shown in FIG. 6, the activation of sense amplifiers SA and SA2 is controlled by a sense enable signal SE from the output part of the AND gate G100.

In the TAG-RAM circuit of FIG. 12, during readout of a tag information TM, a signal of “H” level is sent as a control signal RE. Thereby, when a tag information TM is read out, an N-type transistor N20 connected to a predetermined word line word <i> enters the on state and the dummy bit line dbit is of a ground potential, so that the sense enable signal SE of “H” level is outputted from the output part of the AND gate G100. The subsequent operation is the same as that in the first preferred embodiment, and therefore its description is omitted here.

On the other hand, when writing a tag information TM, a signal of “L” level is sent as a control signal RE. Then, a sense enable signal SE of “L” level is outputted from the output part of the AND gate G100. Upon this, both of the sense amplifiers SA and SA2 are changed to theirs inactive states, so that an activation signal of “L” level is outputted from the output of the sense amplifier SA2, as seen from the configuration of FIG. 7.

Therefore, in the XOR circuit of FIG. 3, the transmission gates TG20 and TG21 maintain the off state and the P-type transistor P20 enters the on state (the inactive state). As the result, no operation is performed and an exclusive OR signal cmp is changed to “L” level.

In addition, since the activation signal EN2 is generated based on the activation signal EN by the delay circuit DLY2 of FIG. 4, the activation signal EN2 is also changed to “L” level during a writing of the tag information TM. Therefore, the AND circuits shown in FIGS. 5 and 10 are also not activated and the precharged state (the inactive state) is maintained.

Thus, the operation of the XOR circuit and AND circuit configuring the comparator 201 in the first or second preferred embodiment can be stopped at the time of writing the tag information TM to the TAG-RAM, thereby reducing the power consumption of the comparator 201.

Fourth Preferred Embodiment

As described above, when an address data 2 is outputted from the CPU in order to read out necessary data, a tag information TM and data are read concurrently from a predetermined address of the cache memory 1, and then it is judged whether the read data is the data that the CPU demands.

As the result, when a judgment signal is of HIT (“H” level), the CPU employs the read data. Therefore, it is generally controlled to detect that the judgment signal is of HIT (“H” level) before the CPU takes data.

Meanwhile, the latch circuits LAT30 and LAT80, configuring the AND circuits shown in FIGS. 5 and 10, respectively, hold and output the result of the preceding judgment signal until a new judgment signal is inputted.

Accordingly, when the preceding judgment signal is of HIT (“H” level), there is the possibility that the CPU takes data based on the preceding judgment signal, without waiting for a new judgment signal that should be judged at this time.

To avoid this, in a comparator 201 of a semiconductor circuit of the fourth preferred embodiment, it is configured such that every time a readout of data is started, a judgment signal is changed to “L” level by initialization for a predetermined period of time.

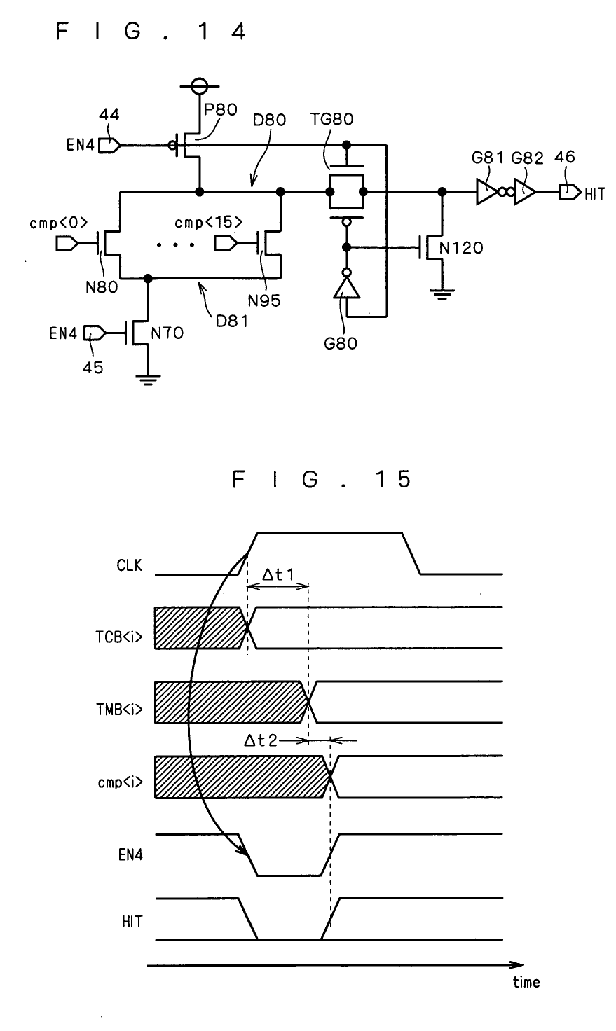

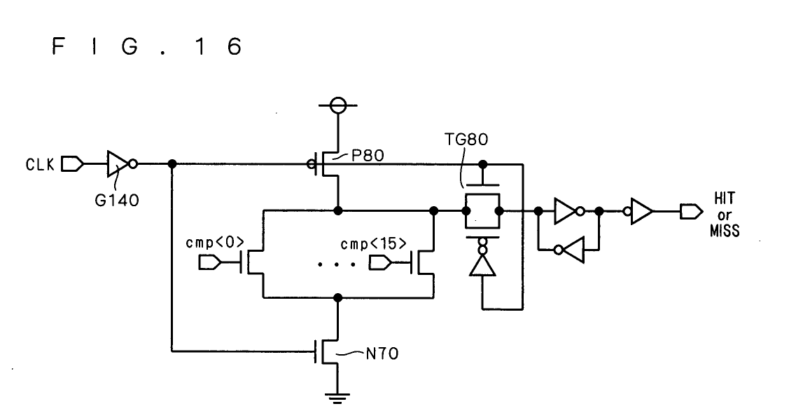

FIG. 13 is a diagram showing a circuit for generating an activation signal that controls initialization and the activation of an AND circuit that is a dynamic circuit. FIG. 14 is a diagram showing the AND circuit that is a dynamic circuit according to the fourth preferred embodiment. The circuit shown in FIG. 13 is located at the front-stage of the AND circuit shown in FIG. 14. The configurations shown in FIGS. 13 and 14 will be described below.

<Circuit Configuration>

The circuit of FIG. 13 is configured by an SR latch circuit G110 and a pulse generator G111 that generates pulses during period of time from the time that a clock signal CLK rises.

In the pulse generator G111, a clock signal CLK is directly inputted to one input part of an AND gate G112, and the clock signal CLK is inputted via a delay circuit DLY4 and inverter G113 to the other input part. The period of time that the pulse generator G111 generates pulses is determined by a delay value of the delay circuit DLY4.

In the SR latch circuit G1110, an activation signal EN2 outputted from the delay circuit DLY2 of FIG. 4 is inputted to a Set input part, and a signal from the output of the pulse generator G111 (i.e., the output of the AND gate G112) is inputted to a Reset input part, and then an activation signal EN4 is outputted from a Q output part to a back-stage AND circuit shown in FIG. 14. Therefore in the fourth preferred embodiment, the activation signal EN4 is inputted as a signal that controls the active state of the AND circuit.

Here, it is assumed that the activation signal EN2 is, as described in the first preferred embodiment, generated based on the activation signal EN by the delay circuit DLY2, and a delay value of the delay circuit DLY2 is set such that the activation signal EN2 rises at the same time that an exclusive OR signal cmp <i> is established on the XOR circuit.

Following is the configuration of the AND circuit that is a dynamic circuit shown in FIG. 14.

The AND circuit of FIG. 14 has approximately the same configuration as the AND circuit shown in FIG. 5 or 10. Specifically, the configuration located before the transmission gate TG22 in FIG. 5 or the transmission gate TG80 in FIG. 10 is the same except for the following different points.

The different points are that the inverter G33 or G83 is removed and that an N-type transistor N120 is added between the input part of the inverter G81 or G31 and ground. The gate of the N-type transistor N120 is connected to the output part of the inverter G30 or G80. That is, FIG. 14 shows a modification of the configuration of FIG. 10 in accordance with the above explanation.

The operation of the above-mentioned circuits will be described based on a timing chart shown in FIG. 15.

<Circuit Operation>

At the same time that a clock signal CLK rises and becomes “H” level, the pulse generator G111 of FIG. 13 initiates the generation of pulses having a predetermined width of “H” level, and the pulses are inputted to the Reset input part of the SR latch circuit G110.

When a pulse signal of “H” level is inputted to the Reset input part of the SR latch circuit G110, an activation signal EN4 of “L” level is outputted from the Q output part of the SR latch circuit G110.

Even if a pulse signal outputted from the pulse generator G111 then falls and a signal of “L” level is inputted to the Reset input part of the SR latch circuit G110, an activation signal EN4 of “L” level is continuously outputted from the Q output part of the SR latch G110 during the period of time that the activation signal EN2 is at “L” level.

Here, the activation signal EN2 rises when time Δt1 (a period of time between the rise of the clock signal CLK and the readout of a tag information TM from the TAG-RAM) and time Δt2 (a period of time between the readout of the tag information and the output of an exclusive OR signal cmp) are elapsed since the clock signal CLK rose.

When the activation signal EN4 of “L” level is generated, the N-type transistor N70 enters the off state and the P-type transistor P80 enters the on state in the AND circuit shown in FIG. 14, so that the AND circuit is precharged and the wiring D80 has a potential of “H” level (the inactive state).

At the same time, the transmission gate TG80 enters the off state and the N-type transistor N120 enters the on state, so that a judgment signal of “L” level is outputted from the output part 46 (the initialization of a judgment signal). That is, a judgment signal indicating “MISS” is outputted from the AND circuit until an exclusive OR signal cmp <i> is outputted on the front-stage XOR circuit (i.e., during the period of time that the activation signal EN2 is at “L” level).

Subsequently, in the front-stage XOR circuit an operation based on the new tag information bit TMB <i> is executed and an exclusive OR signal cmp <i> is outputted as its result. At the same time, the activation signal EN2 rises and becomes “H” level, which is then inputted to the Set input part of the SR latch circuit G110.

Since the signal of “L” is now inputted to the Reset input part of the SR latch circuit G110, an activation signal EN4 of “H” level is outputted from the Q output part of the latch circuit G110.

Then, the P-type transistor P80 and N-type transistor N120 enter the off state and the transmission gate TG80 and N-type transistor N70 enter the on state in the AND circuit shown in FIG. 14. This is the state of performing a judgment processing (the active state). That is, the transition to a HIT/MISS judgment processing occurs at the time that the activation signal EN4 is changed to “H” level.

The subsequent judgment processing of the AND circuit is the same as that in the second preferred embodiment, and a judgment signal of “H” level (HIT) is outputted when all the exclusive OR signals cmp <0:15> are of “L” level (i.e., when a tag information TM matches a reference tag information TC).

On the other hand, when at least one of the exclusive OR signals cmp <0:15> is of “H” level (i.e., when a tag information TM mismatches a reference tag information TC), a judgment signal of “L” level (MISS) is outputted.

Since the activation signal EN2 returns to “L” level when a predetermined time is elapsed since the clock signal CLK fell, the activation signal EN4 is changed to “L” level when the clock signal CLK rises again, as described above. Therefore, the judgment signal of the AND circuit can be initialized to “MISS” before making a judgment based on the next read tag information TM.

The subsequent operation is the same as above, which is to be repeated.

Thus, the judgment signal of the AND circuit can be initialized to “MISS” during a period of time between when the address data 2 is outputted in order that the CPU takes data in synchronization with a lading edge of the clock signal CLK, and when an exclusive OR signal cmp <i> is established based on the address data 2. This eliminates the possibility that the CPU erroneously makes a judgment as to whether data should be taken or not, based on the preceding judgment signal. It is therefore avoidable that the CPU takes any data that should not be taken.

As can be seen from the foregoing operation, it is desirable that a delay value of the delay circuit DLY4 be set so as to be smaller than a period of time between when the clock signal CLK rises and when an exclusive OR signal cmp <i> is established. Otherwise, the AND circuit continues to output a judgment signal of “MISS” although an exclusive OR signal cmp <i> based on a new tag information bit TMB <i> has been established.

In the fourth preferred embodiment, the activation signal EN4 is employed to perform initialization and control the active state of the AND circuit. Although it is possible to employ the activation signal EN2, it should be noted that the use of the activation signal EN4 permits the initialization of a judgment signal in synchronization with the rise of a clock signal CLK.

Fifth Preferred Embodiment

In the comparator 201 of the fourth preferred embodiment, the activation signal EN2 or activation signal EN4 is used to time the activation of the AND circuit that is a dynamic circuit. The AND circuit is activated at the time that the activation signal EN2 or EN4 is changed to “H” level. This timing is required to correspond to the time that an exclusive OR signal cmp <i> is established. For this reason, it is necessary to generate the activation signals EN2 and EN4 by the delay circuit DLY2 and DLY4, respectively.

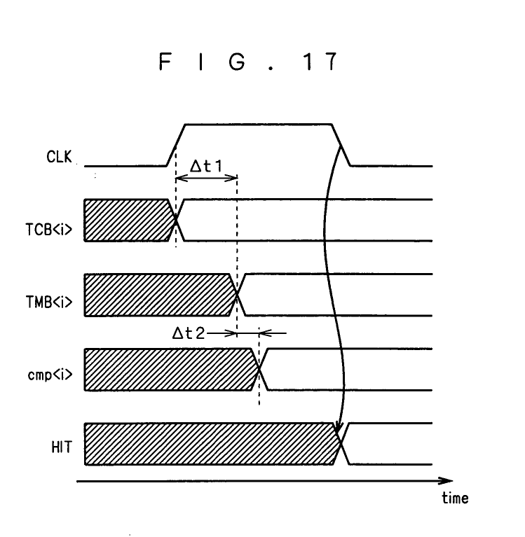

On the other hand, a fifth preferred embodiment employs a clock signal CLK as a signal for controlling the active state of an AND circuit, thereby eliminating the above-mentioned delay circuits. To this end, the fifth preferred embodiment employs an AND circuit that is a dynamic circuit shown in FIG. 16.

The AND circuit of FIG. 16 has the same configuration as the AND circuit of FIG. 10. However, a clock signal CLK that is inverted by an inverter G140 is used as a signal for controlling a P-type transistor P80, N-type transistor N70, and transmission gate TG80.

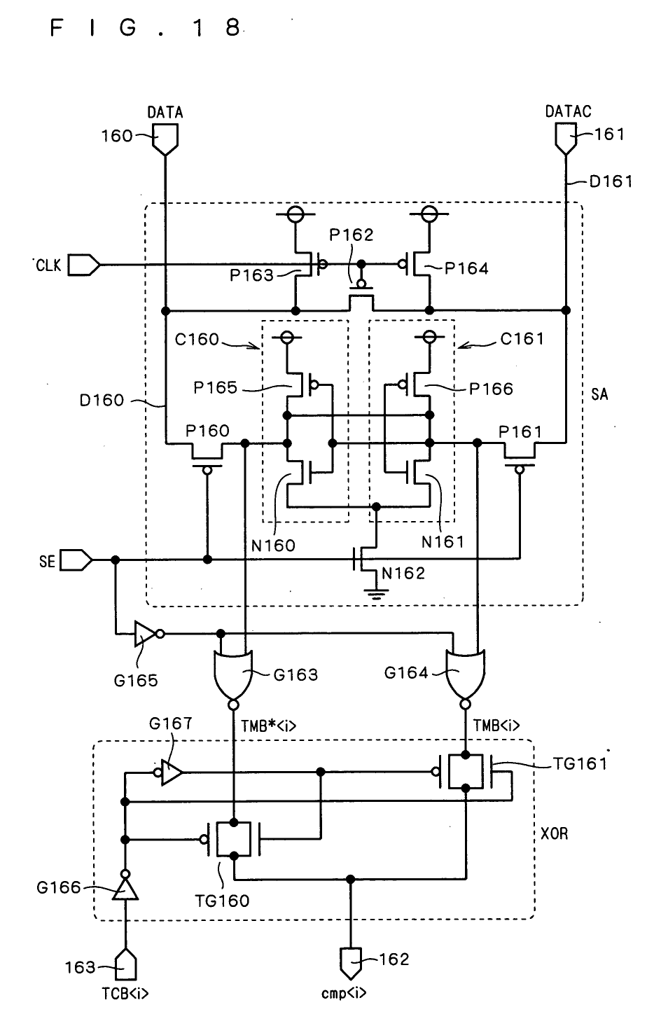

The operation of the AND circuit of the fifth preferred embodiment will be described below based on a timing chart shown in FIG. 17.

First, when a clock signal CLK rises and becomes “H” level, the clock signal CLK is inverted to “L” level by the inverter G140 and then inputted to the respective gates of the P-type transistor P80, N-type transistor N70, and transmission gate TG80.

Then, the P-type transistor P80 enters the on state, the N-type transistor N70 enters the off state, and the transmission gate TG80 enters the off state, so that the AND circuit that is a dynamic circuit is precharged by a fixed power source (the inactive state).

It is assumed that when time Δt1 is elapsed since a clock signal CLK rose, a tag information bit TMB <i> is read out from a TAG-RAM, and when time Δt2 is elapsed thereafter, an exclusive OR signal cmp <i> is established on an XOR circuit and the clock signal CLK falls then.

When the clock signal CLK falls and becomes “L” level, the clock signal CLK is inverted to “H” level by the inverter G140 and then inputted to the respective gates of the P-type transistor P80, N-type transistor N70, and transmission gate TG80.

Then, the P-type transistor P80 enters the off state, the N-type transistor N70 enters the off state, and the transmission gate TG80 enters the on state, so that the AND circuit that is a dynamic circuit is changed to its active state.

The subsequent judgment operation on the AND circuit is the same as that in the second preferred embodiment, and its description is omitted here.

As will be seen from the foregoing operation, in order that the AND circuit of the fifth preferred embodiment perform a proper judgment processing, the cycle tcyc of a clock signal CLK is required to satisfy the following conditions:

tcyc/2>Δt1+Δt2

However, in the operation of memory including the TAG-RAM, time Δt1 that is the time between the start of data readout on the memory and the actual readout of data is usually sufficiently longer than the operation time Δt2 on the XOR circuit (i.e., Δt1>>Δt2).

Further, bit lines are precharged in the later part of the clock cycle tcyc, and a half period of the clock cycle tcyc thereby is sufficiently longer than time Δt1 (i.e., Δt1<<tcyc/2).

Accordingly, the above condition, tcyc/2>Δt1+Δt2, can be satisfied by a proper memory setting.

Thereby, an exclusive OR signal cmp <i> is established on the XOR circuit during a first half period of the clock cycle tcyc, and therefore the, comparator 201 of the fifth preferred embodiment can perform a proper comparison judgment operation.

Thus in the fifth preferred embodiment, the fall of the clock signal CLK is used to activate the AND circuit that is a dynamic circuit, thus requiring no delay circuit. This permits a reduction in the size of the circuit as a whole, as well as a reduction in power consumption.

In addition, the omission of a delay circuit eliminates any malfunction on the circuit that can be caused by variations in the delay circuit characteristic due to parameter change during the delay circuit is in manufacturing.

Although the fifth preferred embodiment is directed to the case of configuring based on the AND circuit shown in FIG. 10, it is also possible to configure based on the AND circuit shown in FIG. 5. That is, the same effect as described above is obtainable by configuring such that in the AND circuit of FIG. 5, a signal obtained by inverting a clock signal CLK is inputted to the gate of the P-type transistor P30.

Sixth Preferred Embodiment

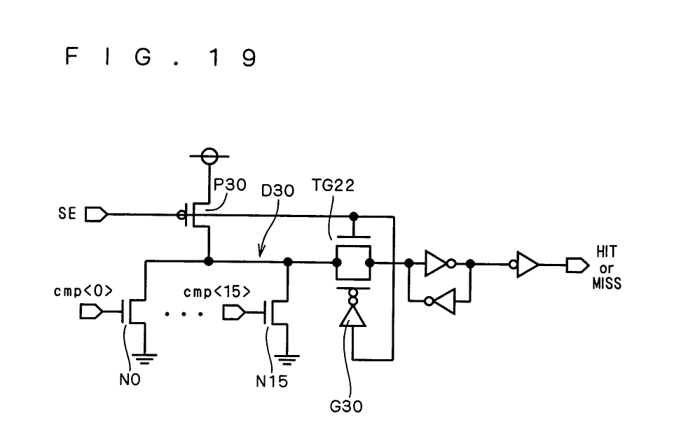

A semiconductor circuit according to a sixth preferred embodiment will be described based on circuit diagrams shown in FIGS. 18 and 19. FIG. 18 is a diagram showing the configuration of a sense amplifier SA outputting a tag information bit TMB <0:15>, an XOR circuit etc. in the sixth preferred embodiment. FIG. 19 is a diagram showing the configuration of an AND circuit that is a dynamic circuit in the sixth preferred embodiment.

<Circuit Configuration>

The circuit configuration shown in FIG. 18 will first be described.

In FIG. 18, a reference character SA represents the sense amplifier SA of the sixth preferred embodiment that is disposed on the TAG-RAM shown in FIG. 6 or FIG. 12.

An input part 160 to which a data line DATA is connected has connection to a wiring D160. An input part 161 to which a data line DATAC is connected has connection to a wiring D161. Between the wirings D160 and D161, two stage circuit groups are connected in parallel to each other.

Following is the configuration of the front-stage circuit group.

One end of a P-type transistor P162 is connected to the wiring D160, and the other end is connected to the wiring D161.

The drain and source of a P-type transistor P163 are connected to one end side of the P-type transistor P162 and a fixed power source, respectively. The drain and source of a P-type transistor P164 are connected to the other end side of the P-type transistor P162 and a fixed power source, respectively. A clock signal CLK is inputted in common to the respective gates of the P-type transistors P162, P163, and P164.

Following is the configuration of the back-stage circuit group.

One end of a P-type transistor P160 is connected to the wiring D160, and one end of a P-type transistor P161 is connected to the wiring D161.

The other end of the P-type transistor P160 is connected to the output side of a CMOS inverter C160 that is configured by connecting in series a P-type transistor P165 and an N-type transistor N160. The other end of the P-type transistor P161 is connected to the output side of a CMOS inverter C161 that is configured by connecting in series a P-type transistor P166 and an N-type transistor N161.

The respective input/output parts of the CMOS inverters C160 and C161 are mutually connected to configure mutually connected CMOS inverters.

The respective sources of the P-type transistors P165 and P166 are connected to a fixed power source, and the respective sources of the N-type transistors N160 and N161 are connected via an N-type transistor N162 to ground.

That is, the CMOS inverters C160, C161, and the P-type transistors P160, P161 configure a static CMOS type memory cell.

A sense enable signal SE is inputted in common to the respective gates of the P-type transistors P160, P161, and the gate of the N-type transistor N162.

The foregoing is a concrete configuration of the sense amplifier SA of the sixth preferred embodiment.

Meanwhile, in the first preferred embodiment, the latch circuit for holding a tag information bit TMB <i> and the driver for driving elements are usually connected to the output side of the sense amplifier SA. This is because when the clock signal CLK is changed to “L” level, the sense amplifier SA is initialized and the output data is deleted.

Specifically, no problem occurs in the case that the operation on the XOR circuit is terminated during the period of time that the clock signal CLK is at “H” level. However, on the XOR circuit under control of the activation signal EN, the operation is not always terminated during the period of time that the clock signal CLK is at “H” level. Therefore, the latch circuit is disposed as a compensation circuit used in the event that the operation is not terminated.

On the other hand, no latch circuit is needed in the sixth preferred embodiment because the XOR circuit is not subject to the control with an activation signal EN. In addition, the driver for driving elements can be omitted because the number of elements to be driven in the XOR circuit of the sixth preferred embodiment is less than that of the first preferred embodiment, as will be described later.

With this configuration, a tag information TMB <i> can be provided to the XOR circuit more quickly than the first preferred embodiment.

In the sixth preferred embodiment, a latch circuit and driver for driving elements are removed, and the sense amplifier SA is connected via NOR gates G163 and G164 to the back-stage XOR circuit.

One input part of the NOR gate G163 is connected to the output side of the CMOS inverter C160. One input part of the NOR gate G164 is connected to the output side of the CMOS inverter C161. A sense enable signal SE is inputted via an inverter G165 in common to the other input part of the NOR gate G163 and the other end of the NOR gate G164.

Following is a concrete description of the XOR circuit of FIG. 18 according to the sixth preferred embodiment.

The XOR circuit has two transmission gates TG160 and TG161. The output of the NOR gate G163 is connected to the input part of the transmission gate TG160, and the output part of the NOR gate G164 is connected to the input part of the transmission gate TG161. The respective output parts of the transmission gates TG160 and TG161 are connected to an output part 162 outputting an exclusive OR signal cmp <i>.

An input part 163 to which a reference bit TCB <i> is inputted is connected via an inverter G166 to a P-type gate of the transmission gate TG160 and an N-type gate of the transmission gate TG161, respectively. Further, the input part 163 is connected via the inverter G166 and an inverter G167 to an N-type gate of the transmission gate TG160 and a P-type gate of the transmission gate TG161, respectively.

The foregoing is the concrete configuration of the XOR circuit in the sixth preferred embodiment.

An AND circuit according to the sixth preferred embodiment shown in FIG. 19 will be described below.

The configuration of this AND circuit is the same as that of the AND circuit shown in FIG. 5, except that instead of the activation signal, a sense enable signal SE is inputted to the gate of a P-type transistor P30 and the gate of a transmission gate TG22.

Following is the operation of a comparator 201 according to the sixth preferred embodiment.

<Circuit Operation>

During a period of time that a clock signal CLK is at “L” level, the P-type transistors P162, P163, and P164 shown in FIG. 18 are in the on state, so that the wirings D160 and D161 connected to the input parts 160 and 161, respectively, are precharged to “H” level.

During the above period, the sense enable signal SE generated by the dummy column DC shown such as FIG. 6 is of course at “L” level. Accordingly, the P-type transistors P160 and P161 enter the on state and the N-type transistor N162 enters the off state.

Thereby, a signal of “H” level is inputted to the respective one input parts of the NOR gates G163 and G164. A signal of “H” level is also inputted to the respective the other input parts because a sense enable signal SE of “L” level passes through the inverter G165. As the result, a signal of “L” level is outputted from the respective output parts of the NOR gates G163 and G164.

In the case that the above “L” level signal is inputted to the back-stage XOR circuit and an “H” level signal is inputted through the input part 163 as a reference bit TCB <i>, the transmission gate TG160 enters the on state, and a signal of “L” level outputted from the NOR gate G163 is outputted from the output part 162 as an exclusive OR signal cmp <i> of “L” level.

On the other hand, in the case that a signal of “L” level is inputted through the input part 163 as a reference bit TCB <i>, the transmission gate TG161 enters the on state, and a signal of “L” level outputted from the NOR gate G164 is outputted from the output part 162 as an exclusive OR signal cmp <i> of “L” level.

Subsequently, a clock signal CLK rises. Referring again to FIG. 6, even if the N-type transistor N20 enters the on state, it takes some time that the electricity taken by a dummy bit line dbit via the N-type transistor N20 is discharged to ground. Therefore, when a predetermined time is elapsed since the clock signal CLK rose, the sense enable signal SE is changed to “H” level.

Accordingly, the sense enable signal SE remains at “L” level during the time that a predetermined time is elapsed since the clock signal CLK rose. Here, the predetermined time is determined by the size of an N-type transistor.

By the sense enable signal SE of “L” level, the P-type transistors P160 and P161 maintain the on state and the N-type transistor N162 maintains the off state. Since the clock signal CLK is changed to “H” level, the P-type transistors P162, P163, and P164 enter the off state.

Due to the potential of a memory cell M that is outputted at the front-stage, a slight potential difference occurs between the wirings D160 and D161, though, “H” level is still maintained.

As discussed above, a signal of “L” level is outputted from the respective output parts of the NOR gates G163 and G164, and a signal of “L” level is outputted as an exclusive OR signal cmp <i> on the back-sage XOR circuit, regardless of whether the reference bit TCB <i> is of “H” or “L” level.

That is, during the period of time that the sense enable signal SE is at “L” level, a signal of “L” level is outputted from the XOR circuit, as an exclusive OR signal cmp <i>.

In an AND circuit shown in FIG. 19 that is located at the back-stage of the XOR circuit, during the period of time that the sense enable signal SE is at “L” level, a P-type transistor P30 is in the on state, a transmission gate TG22 is in the off state, and N-type transistors N0 to N15 used for operation are in the off state, so that precharging is executed properly (the inactive state).

Referring to FIG. 18, when the sense enable signal SE is changed to “H” level, the P-type transistors P160 and P161 enter the off state and the N-type transistor N162 enters the on state. Then, a slight potential difference caused by the tag information bit signal outputted from the front-stage memory cell M is amplified by the CMOS C160 and C161. In accordance with the amplified potential difference, one of the output sides of the CMOS C160 and C161 is changed to “L” level, and the other is changed to “H” level.

If the potential of the output side of the CMOS C161 is of “H” level, a signal of “H” level is inputted to one input part of an NOR gate G164, and a signal of “L” level is inputted to one input part of an NOR gate G163. Since the sense enable signal SE is now at “H” level, a signal of “L” level is inputted in common to the respective the other input parts of the NOR gates G163 and G164.

As the result, a tag information bit TMB <i> of “L” level is outputted from the output part of the NOR gate G164, and a tag information bit TMB*<i> of “H” level is outputted from the output part of the NOR gate G163.

On the other hand, if the potential of the output side of the CMOS C160 is of “H” level, a signal of “H” level is inputted to one input part of the NOR gate G163, and a signal of “L” level is inputted to one input part of the NOR gate G164. Since the sense enable signal SE is at “H” level, a signal of “L” level is inputted in common to the respective the other input parts of the NOR gates G163 and G164.

As the result, a tag information bit TMB <i> of “H” level is outputted from the output part of the NOR gate G164, and a tag information bit TMB*<i> of “L” level is outputted from the output part of the NOR gate G163.

As can be seen from above, when the sense enable signal SE is changed to “H” level, the tag information bit TMB <i> and tag information bit TMB*<i> that have a complementary relationship are inputted to the back-stage XOR circuit.

Consequently, in a first case that a tag information bit TMB <i> is of “H” level and a reference bit TCB <i> is of “H” level, the transmission gate TG160 of the XOR circuit enters the on state, so that an exclusive OR signal cmp <i> of “L” level is outputted from the output part 162.

In a second case that a tag information bit TMB <i> is of “H” level and a reference bit TCB <i> is of “L” level, the transmission gate TG161 of the XOR circuit enters the on state, so that an exclusive OR signal cmp <i> of “H” level is outputted from the output part 162.

In a third case that a tag information bit TMB <i> is of “L” level and a reference bit TCB <i> is of “L” level, the transmission gate TG161 of the XOR circuit enters the on state, so that an exclusive OR signal cmp <i> of “L” level is outputted from the output part 162.

In a fourth case that a tag information bit TMB <i> is of “L” level and a reference bit TCB <i> is of “H” level, the transmission gate TG160 of the XOR circuit enters the on state, so that an exclusive OR signal cmp <i> of “H” level is outputted from the output part 162.

That is, when the tag information TMB <i> matches the reference bit TCB <i>, the exclusive OR signal cmp <i> of “L” level is outputted. On the other hand, when the tag information TMB <i> mismatches the reference bit TCB <i>, the exclusive OR signal cmp <i> of “H” level is outputted.

In the AND circuit shown in FIG. 19, when a signal of “H” level is inputted as a sense enable signal SE, the P-type transistor P30 enters the off state and the transmission gate TG22 enters the on state. Therefore, the AND circuit that is a dynamic circuit is changed to its active state.

In this state, when a signal of “L” level is inputted as exclusive OR signals cmp <0:15> to the individual gates of the N-type transistors N0 to N15 (i.e., when the tag information TM completely matches the reference tag information TC), all the N-type transistors N0 to N15 maintain the off state, thereby outputting an HIT signal of “H” level that has been precharged as a judgment signal.

On the other hand, when at least one of the exclusive OR signals <0:15> is of “H” level (when the tag information TM mismatches the reference tag information TC), the N-type transistors N0 to N15, to the respective gates of which the exclusive OR signal cmp <0:15> of “H” level is inputted, enters the on state and the wiring D30 is changed to be of “L” potential, so that an MISS signal of “L” level is outputted as a judgment signal.

The foregoing is the judgment operation of the comparator in the sixth preferred embodiment, through which a proper judgment processing is performed.

In the XOR circuits according to the first to fifth preferred embodiments, the tag information TMB <i> and TMB*<i> that have a complementary relationship are created within these XOR circuits. Whereas in the XOR circuit of the sixth preferred embodiment, the tag information TMB <i> and TMB*<i> that have a complementary relationship are inputted from the exterior, thus simplifying the configuration of the XOR circuit.

Besides, the following effect is obtainable by using the sense enable signal SE, which also controls the sense amplifier SA outputting a tag information TMB <i>, as a signal for controlling the activation of the AND circuit.

Specifically, in the first to fifth preferred embodiments, it is necessary to activate the AND circuit that is a dynamic circuit at the timing that an exclusive OR signal cmp <i> is established on the XOR circuit. That is, in order to perform a proper judgment processing on the AND circuit, it is necessary to activate the AND circuit after the exclusive OR signal cmp <i> is established. A judgment result can be obtained more quickly with decreasing the time difference between the time at which an exclusive OR signal cmp <i> is established and the time at which the AND circuit is activated.

However, if the above-mentioned time difference is set to an extremely small value, the yield of the comparator 201 is liable to drop. The reason for this is that the initially scheduled time difference varies due to parameter variations in the manufacturing of the comparator 201, and the AND circuit might be activated before an exclusive OR signal cmp <i> is established.

To avoid this, it is usually necessary that the operation margin of the comparator 201 take precedence over the operation speed. Therefore, when employing an AND circuit that is a dynamic circuit, there is a limit on the speed improvement in the AND circuit.

In the comparator 201 of the sixth preferred embodiment, an XOR circuit is configured so as to output a signal (i.e., an exclusive OR signal cmp <i> of “L” level here), by which N-type transistors N0 to N15 used for operation on the back-stage AND circuit are not activated until a tag information TMB <i> that should be judged is inputted (i.e., during the period of time that a sense enable signal SE is at “L” level). On this XOR circuit, a sense enable signal SE that controls the output of the tag information TMB <i> is used as a signal for controlling the activation of the AND circuit, thereby eliminating the necessity of the above-mentioned time margin between the time at which an exclusive OR signal cmp <i> is established and the time at which the AND circuit is activated. It is therefore possible to solve the above-mentioned problem and improve the operation of the comparator 201 as a whole.

Although the sixth preferred embodiment employs the sense enable signal SE as a signal for controlling the activation of the AND circuit, such a signal that can rise more quickly than the sense enable signal SE, under a condition where there is configured an XOR circuit outputting a signal not activating the N-type transistors N0 to N15 used for operation on the back-stage AND circuit (The XOR circuit of the first preferred embodiment satisfies this condition). It should be noted that the AND circuit can be activated in a simple circuit design and at the best timing by using the sense enable signal SE.

Instead of the NOR gates G163 and G164, two inverters may be used as a gate for outputting a tag information bit TMB <i> and a tag information bit TMB*<i> that have a complementary relationship. The following effect is obtainable by using the NOR gates G163 and G164 and employing the sense enable signal SE to control the output of the NOR gates G163 and G164.

That is, consider now the case of writing a tag information TM in the TAG-RAM. One of the data lines DATA and DATAC becomes “H” level, and the other becomes “L” level. In this case, if the inverters were used instead of the NOR gates G163 and G164, the comparator 201 at the back-stage could be activated during a writing of data.

On the other hand, when a tag information TM is written in the TAG-RAM by using the NOR gates G163 and G164 so as to permit the control with the sense enable signal SE, the sense enable signal SE is at “L” level and an exclusive OR signal is also fixed at “L” level during a writing, so that the comparator 201 is not activated.

Thus, the comparator 201 is activated only during the time of readout, thereby saving power consumption.

In the foregoing preferred embodiments, the tag information TM stored in the TAG-RAM has been discussed by way of example and without limitation. It is of course possible to apply to a semiconductor circuit having a comparator that compares a first multi-bit data stored in any other general memory (storage unit) with a second multi-bit data from a CPU.

While the invention has been shown and described in detail, the foregoing description is in all aspects illustrative and not restrictive. It is therefore understood that numerous modifications and variations can be devised without departing from the scope of the invention.

What is claimed is:

1. A semiconductor circuit having a storage unit storing a first multi-bit data and a comparator comparing said first data with a second multi-bit data, wherein
an active state of said comparator is controlled based on a first control signal for controlling the output of said first data from said storage unit.

2. The semiconductor circuit according to claim 1 wherein
said storage unit includes a sense amplifier outputting a first activation signal,
an active state of said sense amplifier is controlled by said first control signal, and
said comparator is controlled based on said first activation signal outputted from said sense amplifier.

3. The semiconductor circuit according to claim 2 wherein said comparator includes:
a plurality of exclusive OR circuits performing an exclusive OR operation of the corresponding bits between said first data and said second data; and
an AND circuit performing an AND operation of exclusive OR signals outputted from said plurality of exclusive OR circuits, respectively.

4. The semiconductor circuit according to claim 3 wherein
active state/inactive state of said exclusive OR circuits are controlled by said first activation signal.

5. The semiconductor circuit according to claim 4 wherein
said AND circuit is a dynamic circuit which performs during its active state an AND operation of exclusive OR signals outputted from said plurality of exclusive OR circuits, and to which precharging is executed during its inactive state, active state/inactive state of said AND circuit being controlled by a clock signal.

6. The semiconductor circuit according to claim 3 further including:
a delay circuit that converts said first activation signal to a second activation signal by giving said first activation signal a time delay equal to or more than the operation time on said exclusive OR circuit, wherein
said AND circuit is a dynamic circuit which performs during its active state an AND operation of exclusive OR signals outputted from said plurality of exclusive OR circuits, and to which precharging is executed during its inactive state, active state/inactive state of said AND circuit being controlled by said second activation signal.

7. The semiconductor circuit according to claim 4 further including:
a delay circuit that converts said first activation signal to a second activation signal by giving said first activation signal a time delay equal to or more than the operation time on said exclusive OR circuit, wherein
said AND circuit is a dynamic circuit which performs during its active state an AND operation of exclusive OR signals outputted from said plurality of exclusive OR circuits, and to which precharging is executed during its inactive state, active state/inactive state of said AND circuit being controlled by said second activation signal.

8. The semiconductor circuit according to claim 6 wherein
said AND circuit includes:
a group of transistors performing operation that are connected in parallel to each other;
a transistor of a first conductivity type connecting respective one ends of said transistor group to a fixed power source; and
a transistor of a second conductivity type connecting respective the other ends of said transistor group to ground, and
said second activation signal is used to control such that only one of said transistor of the first conductivity type and said transistor of the second conductivity type enters the on state.

9. The semiconductor circuit according to claim 7 wherein
said AND circuit includes:
a group of transistors performing operation that are connected in parallel to each other;
a transistor of a first conductivity type connecting respective one ends of said transistor group to a fixed power source; and
a transistor of a second conductivity type connecting respective the other ends of said transistor group to ground, and
said second activation signal is used to control such that only one of said transistor of the first conductivity type and said transistor of the second conductivity type enters the on state.

10. The semiconductor circuit according to claim 1 wherein
said comparator does not perform any comparison processing when said first data is written in said storage unit, and performs a comparison processing when said first data is read from said storage unit.

11. The semiconductor circuit according to claim 10 wherein
said storage unit further includes a logic gate for controlling the output of said first control signal, said logic gate being controlled by a second control signal.

12. The semiconductor circuit according to claim 6 wherein
an output signal from said AND circuit maintains a predetermined initialization state until a desired output signal outputted from said exclusive OR circuit is established.

13. The semiconductor circuit according to claim 7 wherein
an output signal from said AND circuit maintains a predetermined initialization state until a desired output signal outputted from said exclusive OR circuit is established.

14. The semiconductor circuit according to claim 12 wherein
said AND circuit includes a transistor for initialization, one end of which is connected to the output side of said AND circuit, and the other end is connected to a fixed power source, and
said transistor for initialization is controlled based on said second activation signal so as to become conductive until a desired output signal outputted from said exclusive OR circuit is established.

15. The semiconductor circuit according to claim 13 wherein
said AND circuit includes a transistor for initialization, one end of which is connected to the output side of said AND circuit, and the other end is connected to a fixed power source, and
said transistor for initialization is controlled based on said second activation signal so as to become conductive until a desired output signal outputted from said exclusive OR circuit is established.

16. The semiconductor circuit according to claim 14 further including:
a pulse generator generating a pulse signal in synchronization with a clock signal; and
a latch circuit having a Reset input part to which said pulse signal is inputted, a Set input part to which said second activation signal is inputted, and an output part outputting a third activation signal generated from said pulse signal and said second activation signal, wherein
said transistor for initialization is controlled by said third activation signal.

17. The semiconductor circuit according to claim 15 further including:
a pulse generator generating a pulse signal in synchronization with a clock signal; and
a latch circuit having a Reset input part to which said pulse signal is inputted, a Set input part to which said second activation signal is inputted, and an output part outputting a third activation signal generated from said pulse signal and said second activation signal, wherein
said transistor for initialization is controlled by said third activation signal.

18. The semiconductor circuit according to claim 16 wherein
active state/inactive state of said AND circuit are controlled by said third activation signal.

19. The semiconductor circuit according to claim 17 wherein
active state/inactive state of said AND circuit are controlled by said third activation signal.

20. The semiconductor circuit according to claim 1 wherein
said comparator includes:
a plurality of exclusive OR circuits performing an exclusive OR operation of the corresponding bits between said first data and said second data; and
said AND circuit is a dynamic circuit which performs during its active state an AND operation of exclusive OR signals outputted from said plurality of exclusive OR circuits, and to which precharging is executed during its inactive state, active state/inactive state of said AND circuit being controlled by said first control signal.

21. The semiconductor circuit according to claim 20 wherein
said AND circuit includes a group of transistors performing an AND operation, and
said exclusive OR circuit is a circuit outputting a signal not activating said group of transistors of said AND circuit until said first data is inputted.

22. The semiconductor circuit according to claim 20 wherein
said first data and a third data having a complementary relationship with said first data are inputted to said exclusive OR circuit.

23. The semiconductor circuit according to claim 22 wherein
the output of said first data and said third data is controlled by said first control signal.
